(19) United States
(12) Patent Application Publication
(10) Pub. No.: US 2026/0190824 A1
(43) Pub. Date: Jul. 2, 2026

(54) DISPLAY PANEL, AND ELECTRONIC DEVICE INCLUDING THE SAME

(71) Applicant: SAMSUNG DISPLAY CO., LTD., YONGIN-SI (KR)

(72) Inventor: Kyeongjong Kim, YONGIN-SI (KR)

(21) Appl. No.: 19/243,054

(22) Filed: Jun. 19, 2025

(30) Foreign Application Priority Data
Dec. 31, 2024 (KR) 10-2024-0202731

(51) Int. Cl. H10K 59/80

(52) U.S. Cl. CPC H10K 59/8792

(57) ABSTRACT

A display panel includes a substrate. A first light-emitting diode is disposed on the substrate. The first light-emitting diode includes a first pixel electrode, an intermediate layer, and an opposite electrode. A first absorption pattern is disposed on the first light-emitting diode. The first absorption pattern overlaps the first pixel electrode in a plan view and includes an opening overlapping a portion of the first pixel electrode in the plan view. A first reflection pattern is disposed on the first absorption pattern and overlaps the opening of the first absorption pattern in the plan view. A first light-blocking pattern is disposed on the first reflection pattern and overlaps the opening of the first absorption pattern in the plan view.

### CROSS-REFERENCE TO RELATED APPLICATION

This application claims priority under 35 U.S.C. §119 to Korean Patent Application No. 10-2024-0202731, filed on December 31, 2024 in the Korean Intellectual Property Office, the present disclosure of which is incorporated by reference in its entirety herein.

### TECHNICAL FIELD

One or more embodiments relate to a display panel and an electronic device including the display panel.

### DISCUSSION OF RELATED ART

Display apparatuses are electronic devices that display various moving and/or still images. Display apparatuses provide images to a viewer by using light-emitting diodes. Applications of display apparatuses have become increasingly diverse. Research is being conducted to increase the quality of display apparatuses.

### SUMMARY

One or more embodiments include a display panel having a structure capable of reducing external light reflectance and recycling light emitted by a light-emitting diode. One or more embodiments include an electronic device including the display panel. Of course, the scope of the present disclosure is not limited to these purposes.

Additional aspects will be set forth in part in the description which follows and, in part, will be apparent from the description, or may be learned by practice of the presented embodiments of the present disclosure.

According to an embodiment of the present disclosure, a display panel includes a substrate. A first light-emitting diode is disposed on the substrate. The first light-emitting diode includes a first pixel electrode, an intermediate layer, and an opposite electrode. A first absorption pattern is disposed on the first light-emitting diode. The first absorption pattern overlaps the first pixel electrode in a plan view and includes an opening overlapping a portion of the first pixel electrode in the plan view. A first reflection pattern is disposed on the first absorption pattern and overlaps the opening of the first absorption pattern in the plan view. A first light-blocking pattern is disposed on the first reflection pattern and overlaps the opening of the first absorption pattern in the plan view.

In an embodiment, the display panel may further include a touch input layer including a first touch electrode disposed on the first absorption pattern and a second touch electrode disposed on the first touch electrode, and the first reflection pattern may be disposed on a same layer as one of the first touch electrode and the second touch electrode.

In an embodiment, the first reflection pattern may be disposed on the same layer as the first touch electrode.

In an embodiment, the first absorption pattern may include a plurality of openings, and the display panel may include a plurality of first reflection patterns overlapping the plurality of openings, respectively, and a plurality of first light-blocking patterns overlapping the plurality of openings, respectively.

In an embodiment, the first light-blocking pattern may include a material that transmits light of a different color from light emitted by the first light-emitting diode.

In an embodiment, the display panel may further include a reflection control layer disposed on the first light-blocking pattern, and the reflection control layer may absorb light of a different wavelength band from the light emitted by the first light-emitting diode.

In an embodiment, the display panel may further include a second light-emitting diode disposed on the substrate. The second light-emitting diode is spaced apart from the first light-emitting diode. A first color filter is disposed on the first light-emitting diode. The first color filter transmits light having a same color as light emitted by the first light-emitting diode. A second color filter is disposed on the second light-emitting diode. The second color filter transmits light having a same color as light emitted by the second light-emitting diode.

In an embodiment, the first color filter may cover the first light-blocking pattern.

In an embodiment, the display panel may further include a light-blocking layer disposed on the first reflection pattern. The light-blocking layer includes a first hole overlapping the first light-emitting diode.

In an embodiment, the first light-blocking pattern may be disposed on a same layer as the light-blocking layer.

In an embodiment, the first light-blocking pattern may include a same material as a material included in the second color filter.

In an embodiment, the first light-blocking pattern may be disposed on the first color filter.

In an embodiment, the display panel may further include a second light-blocking pattern disposed on the second light-emitting diode, and the second light-blocking pattern may include a same material as a material included in the first color filter.

In an embodiment, the first color filter and the second color filter may overlap each other in an area between the first light-emitting diode and the second light-emitting diode.

In an embodiment, the display panel may further include a pixel defining layer disposed on the first pixel electrode. The pixel defining layer includes a light-emitting opening that defines an emission area of the first light-emitting diode.

In an embodiment, in the plan view, an area of the opening of the first absorption pattern may be in a range of about 5% to about 15% of an area of the light-emitting opening of the pixel defining layer.

In an embodiment, in the plan view, a shape of the opening of the first absorption pattern and a shape of the light-emitting opening of the pixel defining layer may be different from each other.

According an embodiment of the present disclosure, an electronic device may include a display panel. The display panel including a substrate. A first light-emitting diode is disposed on the substrate. The first light-emitting diode includes a first pixel electrode, an intermediate layer, and an opposite electrode. A first absorption pattern is disposed on the first light-emitting diode. The first absorption pattern overlaps the first pixel electrode in a plan view and includes an opening overlapping a portion of the first pixel electrode in the plan view. A first reflection pattern is disposed on the first absorption pattern and overlaps the opening of the first absorption pattern in the plan view. A first light-blocking pattern is disposed on the first reflection pattern and overlaps the opening of the first absorption pattern in the plan view.

In an embodiment, the display panel may further include a touch input layer including a first touch electrode disposed on the first absorption pattern and a second touch electrode disposed on the first touch electrode, and the first reflection pattern may be disposed on a same layer as one of the first touch electrode and the second touch electrode.

In an embodiment, the display panel may further include a reflection control layer disposed on the first light-blocking pattern, and the reflection control layer may absorb light of a different wavelength band from the light emitted by the first light-emitting diode.

### BRIEF DESCRIPTION OF THE DRAWINGS

The above and other aspects, features, and advantages of certain non-limiting embodiments of the present disclosure will be more apparent from the following description taken in conjunction with the accompanying drawings, in which:

FIG. 1 is a block diagram of an electronic device according to an embodiment of the present disclosure;

FIGS. 2, 3 and 4 are schematic views of electronic devices according to embodiments of the present disclosure;

FIG. 5 is a schematic plan view of a display panel according to an embodiment of the present disclosure;

FIG. 6 is an equivalent circuit diagram of a pixel of a display panel according to an embodiment of the present disclosure;

FIG. 7 is a cross-sectional view of a display panel according to an embodiment of the present disclosure;

FIG. 8 is a cross-sectional view of a display panel according to an embodiment of the present disclosure;

FIG. 9 is a cross-sectional view of a display panel according to an embodiment of the present disclosure;

FIG. 10 is a cross-sectional view of a display panel according to an embodiment of the present disclosure;

FIG. 11 is a cross-sectional view of a display panel according to an embodiment of the present disclosure;

FIG. 12 is a cross-sectional view of a display panel according to an embodiment of the present disclosure;

FIG. 13 is a cross-sectional view of a display panel according to an embodiment of the present disclosure;

FIG. 14 is a plan view of a display panel according to an embodiment of the present disclosure;

FIG. 15 is a plan view of a display panel according to an embodiment of the present disclosure;

FIG. 16 is a plan view of a display panel according to an embodiment of the present disclosure; and

FIG. 17 is a plan view of a display panel according to an embodiment of the present disclosure.

### DETAILED DESCRIPTION OF EMBODIMENTS

Reference will now be made in detail to non-limiting embodiments, examples of which are illustrated in the accompanying drawings, wherein like reference numerals refer to like elements throughout. In this regard, the present embodiments may have different forms and should not be construed as being limited to the descriptions set forth herein. Accordingly, non-limiting embodiments are merely described below, by referring to the figures, to explain aspects of the present description. As used herein, the term "and/or" includes any and all combinations of one or more of the associated listed items. Throughout the present disclosure, the expression "at least one of a, b or c" indicates only a, only b, only c, both a and b, both a and c, both b and c, all of a, b, and c, or variations thereof.

As the present disclosure allows for various changes and numerous embodiments, particular non-limiting embodiments will be illustrated in the drawings and described in detail in the written description. Hereinafter, effects and features of the present disclosure and a method for accomplishing them will be described more fully with reference to the accompanying drawings, in which embodiments of the present disclosure are shown. The present disclosure may, however, be embodied in many different forms and should not be construed as limited to described embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that, unless otherwise specified, when an element such as a layer, film, region or substrate is referred to as being "on" another element, it can be "directly" on the other element or intervening elements may also be present. In the drawings, the thicknesses of layers and regions are exaggerated or reduced for convenience of explanation. For example, since sizes and thicknesses of components in the drawings may be arbitrarily illustrated for convenience of explanation, embodiments are not necessarily limited thereto.

It will be understood that although the terms "first," "second," etc. may be used herein to describe various components, these components should not be limited by these terms. These components are only used to distinguish one component from another.

It will be further understood that the terms "comprises" and/or "comprising" used herein specify the presence of stated features or components, but do not preclude the presence or addition of one or more other features or components.

In the present specification, "A and/or B" represents A or B, or A and B. The expression "at least one of A and B" indicates only A, only B, both A and B, or variations thereof.

It will also be understood that when a layer, region, or component is referred to as being "connected" or "coupled" to another layer, region, or component, it can be directly connected or coupled to the other layer, region, or component or intervening layers, regions, or components may be present. For example, when a layer, region, or component is referred to as being "electrically connected" or "electrically coupled" to another layer, region, or component, it can be directly electrically connected or coupled to the other layer, region, or component or intervening layers, regions, or components may be present. When a layer, region, or component is referred to as being "directly connected" or "directly coupled" to another layer, region, or component, no intervening layers may be present.

In embodiments below, an expression 'x direction' may refer to a +x direction and a -x direction, such as ±x directions. In embodiments below, an expression 'y direction' may refer to a +y direction and a -y direction, such as ±y directions. In embodiments below, an expression 'z direction' may refer to a +z direction and a -z direction, such as ±z directions.

Display apparatuses according to embodiments are applicable to various electronic devices. An electronic device according to an embodiment may include a display apparatus, and may further include a module or device having other additional functions in addition to the display apparatus. A display apparatus according to an embodiment may include a display panel.

The present disclosure concerns a display device that includes an absorption layer disposed on a light-emitting diode. The absorption layer may include a material having a refractive index greater than or equal to about 1.0 and an absorption coefficient greater than or equal to about 0.5. The absorption layer reduces external light being reflected by a pixel electrode. The absorption layer has an opening overlapping a portion of the pixel electrode in a plan view. A reflection pattern overlaps the opening of the absorption layer in a plan view. A light-blocking pattern may overlap the reflection pattern to block external light from reaching the reflection pattern.

Light emitted by the light-emitting diode may pass through the opening in the absorption layer and may be reflected by the reflection pattern to be re-incident towards the pixel electrode. The light may then be reflected by the pixel electrode towards the viewer. Therefore, the light emitted by the light-emitting diode may be recycled which provides an increase in the efficiency of the display panel and an increase in the image quality of the displayed images.

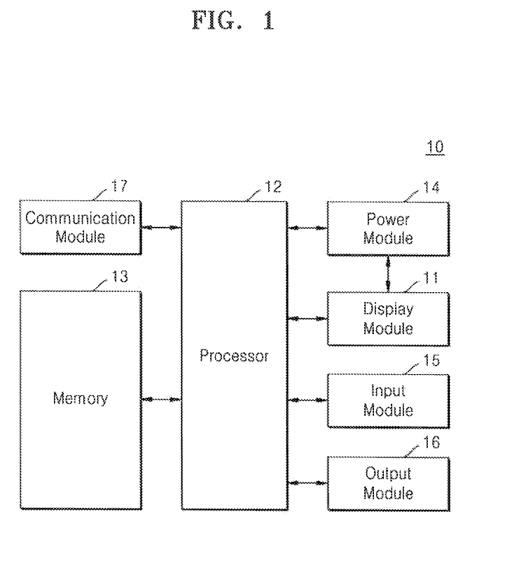

FIG. 1 is a block diagram of an electronic device 10 according to an embodiment. Referring to FIG. 1, in an embodiment the electronic device 10 may include a display panel 11 (e.g., a display module), a processor 12, a memory 13, and a power module 14.

In an embodiment, the processor 12 may include at least one of a central processing unit (CPU), an application processor (AP), a graphics processing unit (GPU), a communication processor (CP), an image signal processor (ISP), and a controller. According to an embodiment, the processor 12 may be provided as two or more processors divided by functional or structural aspects. For example, the processor 12 may include a main processor in the form of a first drive chip including a CPU, and an auxiliary processor in the form of a second drive chip including a controller that receives an image signal from the main processor and processes the image signal to conform to the interface specifications of the display panel 11.

In an embodiment, the memory 13 may include at least one of a non-volatile memory and a volatile memory. The memory 13 may store data information necessary for an operation of the processor 12 or the display panel 11. When the processor 12 executes an application stored in the memory 13, an image data signal and/or an input control signal may be transmitted to the display panel 11, and the display panel 11 may process the received signal and output image information through a display screen.

The power module 14 may include a power supply module, such as a power adapter or a battery device, and a power conversion module that converts power supplied by the power supply module to generate power necessary for an operation of the electronic device 10. Power conversion by the power conversion module may include, but is not necessarily limited to, DC-to-DC conversion, AC-to-DC conversion, and DC-to-AC conversion.

In an embodiment, the electronic device 10 may further include an input module 15, a non-image output module 16, and/or a communication module 17.

The input module 15 may provide input information to the processor 12 and/or the display panel 11. The input module 15 may include various sensor modules as well as physical buttons, a keyboard, and a microphone. Examples of the sensor modules may include a touch sensor, a pressure sensor, a distance sensor, a position sensor, a digitizer, a motion recognition sensor, a camera sensor, a light-receiving sensor, a photoelectric conversion sensor, and a temperature sensor, as well as biosensors, such as a blood pressure sensor, a blood sugar sensor, an electrocardiogram sensor, and a heart rate sensor.

The non-image output module 16 may receive information other than an image received from the processor 12, and may provide the information to a user. Examples of the non-image output module 16 may include a sound module, a haptic module, a light-emitting module, and may include other functional modules unique to a specific electronic device (e.g., a cooling module of a refrigerator, etc.).

The communication module 17, which is a module responsible for transmitting and receiving information between the electronic device 10 and an external device, may include a reception unit and a transmission unit. In an embodiment, the communication module 17 may include various wireless communication modules, such as a mobile communication module, a Wi-Fi module, and a Bluetooth module, or various wired communication modules.

At least one of the components of the electronic device 1000 described above may be included in display apparatuses according to the aforementioned embodiments. In addition, some of the individual modules functionally included within a module may be included within a display apparatus, and the others may be provided separately from the display apparatus. For example, the display apparatus may include the display panel 11, and the processor 12, the memory 13, and the power module 14 may be provided in the form of other devices within the electronic device 1000 rather than the display apparatus. As another example, the power module 14 may be provided within the display apparatus, and may supply power to the processor 12 and the memory 13 provided within the electronic device 10 other than the display apparatus. However, embodiments are not necessarily limited to the above examples.

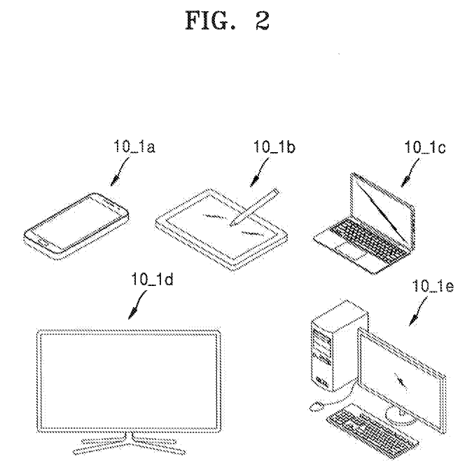

FIGS. 2 through 4 are schematic views of electronic devices according to various embodiments. FIGS. 2 through 4 illustrate various electronic devices to which display apparatuses according to embodiments are applied.

FIG. 2 illustrates, as examples of electronic devices, a smartphone 10_1a, a tablet PC 10_1b, a laptop 10_1c, a TV 10_1d, and a computer monitor 10_1e.

The smartphone 10_1a may include an input module, such as a touch sensor, and a communication module, in addition to a display panel. The smartphone 10_1a may process information received through the communication module or other input modules, and may display the information through the display panel of the display apparatus.

Even the tablet PC 10_1b, the laptop 10_1c, the TV 10_1d, and the computer monitor 10_1e may include a display panel and an input module, similar to the smartphone 10_1a. In some embodiments, the tablet PC 10_1b, the laptop 10_1c, the TV 10_1d, and the computer monitor 10_1e may further include communication modules.

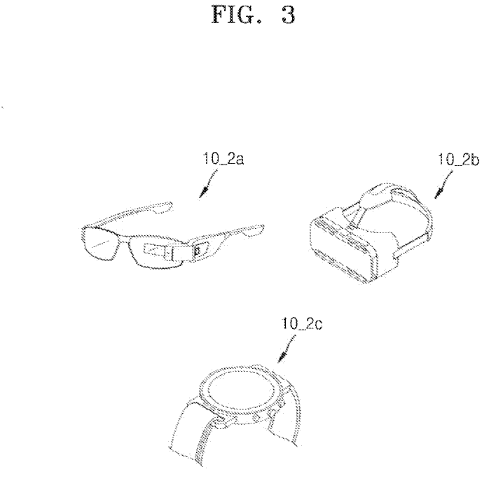

FIG. 3 illustrates a case where an electronic device including a display panel is applied to a wearable electronic device. The wearable electronic device may be smart glasses 10_2a, a head mounted display 10_2b, a smart watch 10_2c, or the like.

The smart glasses 10_2a and the head mounted display 10_2b may include a display panel for emitting a display image and a reflector for reflecting the emitted display image to provide a result of the reflection to the user's eyes, thereby providing a virtual reality or augmented reality screen image to the user.

The smart watch 10_2c may include a biosensor as an input device, and may provide biometric information recognized by the biosensor to the user through a display panel.

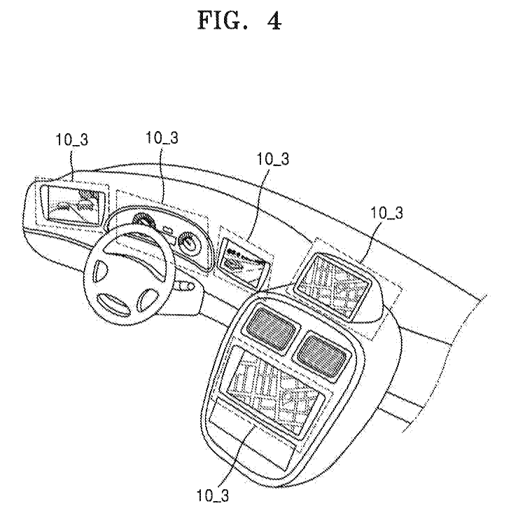

FIG. 4 illustrates an embodiment where an electronic device including a display panel is applied to a vehicle. For example, the electronic device 10 may be applied to dashboards, center fasciae, etc. of automobiles, or may be applied to, for example, center information displays (CIDs) arranged on the dashboards of automobiles or room mirror displays that replace the side mirrors of automobiles.

In some embodiments, electronic devices to which display apparatuses according to embodiments are applied may include not only devices that mainly perform screen display, such as a billboard, an electronic board, and a game console, but also various home appliances that display information through display panels, such as a refrigerator, a washing machine, a dryer, an air conditioner, and a robot vacuum cleaner. In addition, when a display panel has a function of transmitting light, the display panel may be applied to electronic devices, such as smart windows or transparent display apparatuses that display both a background and a displayed image. The types of electronic devices according to embodiments are not limited to the examples above, and application of various other small, medium or large-sized electronic devices is also possible.

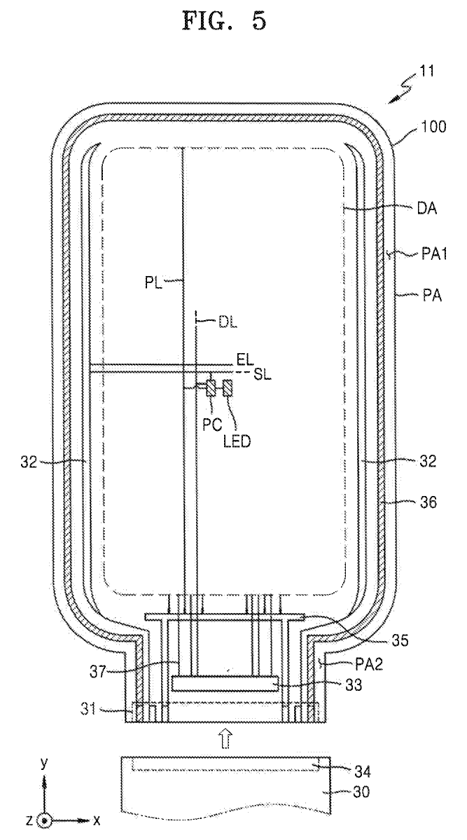

FIG. 5 is a schematic plan view of a display panel 11 according to an embodiment.

Referring to FIG. 5, the display panel 11 may include a display area DA and a peripheral area PA outside the display area DA (e.g., in a plan view). The display area DA, in which an image is displayed, may include a plurality of pixels arranged thereon. The display area DA may have any of various shapes such as a circular shape, an oval shape, a polygonal shape, and a particular figure shape (e.g., in a plan view). For example, FIG. 5 illustrates that the display area DA has a substantially rectangular shape with rounded corners.

The peripheral area PA may be disposed outside the display area DA (e.g., in a plan view). In an embodiment, the peripheral area PA may include a first peripheral area PA1 surrounding at least a portion of the display area DA, and a second peripheral area PA2 adjacent to one side of the display area DA and extending in the y direction. A width of the second peripheral area PA2 in the x direction may be less than a width of the display area DA in the x direction. This structure may facilitate bending of at least a portion of the second peripheral area PA2. According to an embodiment, the display panel 11 may be bent about a bending axis extending across the second peripheral area PA2.

A planar shape of the display panel 11 of FIG. 5 may be substantially the same as a planar shape of a substrate 100 included in the display panel 11. The display panel 11 including the display area DA and the peripheral area PA outside the display area DA may have substantially the same meaning as the substrate 100 including the display area DA and the peripheral area PA outside the display area DA or the display area DA and the peripheral area PA outside the display area DA being defined on the substrate 100. For convenience of explanation, the substrate 100 will now be described as including the display area DA and the peripheral area PA.

In an embodiment, the substrate 100 may include glass, a metal, or a polymer resin. For example, in an embodiment the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the aforementioned polymer resin and an inorganic material layer interposed between the two layers.

Pixels may be arranged in the display area DA. The display panel 11 may provide an image through light emitted by the pixels (e.g., the subpixels of the pixels).

According to an embodiment, each of the pixels may include a plurality of subpixels. In an embodiment, each of the plurality of subpixels may be a subpixel configured to emit light of different colors from each other. According to an embodiment, one pixel may include a red subpixel, a green subpixel, and a blue subpixel. According to an embodiment, one pixel may include a red subpixel, a green subpixel, a blue subpixel, and a white subpixel. Each of the plurality of subpixels may include a pixel circuit PC, and a light-emitting diode LED electrically connected to the pixel circuit PC.

According to an embodiment, each of the pixels may include one pixel circuit PC, and one light-emitting diode LED. In the display area DA, a plurality of pixels emitting different light beams may be arranged. According to an embodiment, a red pixel, a green pixel, and a blue pixel may be arranged in the display area DA. According to an embodiment, a red pixel, a green pixel, a blue pixel, and a white pixel may be arranged in the display area DA.

A pixel used herein may refer to a pixel including a plurality of subpixels, each having a light-emitting diode LED, or may refer to a pixel having a single light-emitting diode LED.

In an embodiment, a pad portion 31, a scan driver 32, a data driver 33, a driving voltage supply line 35, a common voltage supply line 36, and an input line 37 may be arranged in the peripheral area PA.

The scan driver 32 may provide a scan signal to a pixel circuit PC via a scan line SL. The scan line SL may be a gate line connected to gates of switching transistors included in the pixel circuit PC. In an embodiment, the scan signal may be a gate signal that turns on or off the switching transistors included in the pixel circuit PC. In an embodiment, scan drivers 32 may be disposed on both sides of the peripheral area PA with the display area DA therebetween (e.g., in the x direction). Some of the pixel circuits PC arranged in the display area DA may be electrically connected to the scan drivers 32 arranged in the -x direction, and the remaining pixel circuits PC may be electrically connected to the scan drivers 32 arranged in the +x direction. According to an embodiment, a scan driver 32 may be disposed on one side of the peripheral area PA.

The pad portion 31 may be disposed on one side of the second peripheral area PA2 of the substrate 100. The pad portion 31 may be exposed without being covered by an insulating layer, and may be electrically connected to a display circuit board 30. A pad portion 34 of the display circuit board 30 may be electrically connected to the pad portion 31 of the display panel 11.

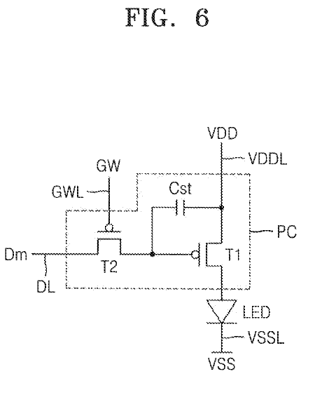

The display circuit board 30 may transmit a control signal to the display panel 11. The control signal may be transmitted to the scan driver 32 and the data driver 33 via the display circuit board 30. According to an embodiment, the display circuit board 30 may include a power management integrated circuit (IC). The power management IC may provide a first power supply voltage VDD (see FIG. 6) and a second power supply voltage VSS (see FIG. 6) to the driving voltage supply line 35 and the common voltage supply line 36, respectively. The first power supply voltage VDD may be provided to each of the pixel circuits PC via a driving voltage line PL connected to the driving voltage supply line 35, and the second power supply voltage VSS may be provided to an opposite electrode of a light-emitting diode LED connected to the common voltage supply line 36. The driving voltage supply line 35 may extend in the x direction. The common voltage supply line 36 may partially surround the display area DA by having a loop shape of which one side is open.

A data signal of the data driver 33 may be transmitted to an input line 37 and a data line DL electrically connected to the input line 37.

FIG. 6 is an equivalent circuit diagram of a pixel of a display panel according to an embodiment.

Referring to FIG. 6, a light-emitting diode LED corresponding to a pixel may be electrically connected to a pixel circuit PC. The pixel circuit PC may include a first transistor T1, a second transistor T2, and a storage capacitor Cst. The pixel circuit PC may be electrically connected to signal lines and voltage lines. The signal lines may include a scan signal line GWL and a data line DL, and the voltage lines may include a first voltage line VDDL.

The second transistor T2, which is a data write transistor, may be electrically connected to the scan signal line GWL and the data line DL. In an embodiment, the scan signal line GWL may be configured to provide a scan signal GW to a gate electrode of the second transistor T2. The second transistor T2 may be configured to transmit a data signal Dm to the first transistor T1 according to the scan signal GW input from the scan signal line GWL, wherein the data signal Dm is input from the data line DL.

In an embodiment, the storage capacitor Cst may be electrically connected to the second transistor T2 and the first voltage line VDDL, and may store a voltage corresponding to a difference between a voltage received from the second transistor T2 and the first power supply voltage VDD supplied by the first voltage line VDDL.

The first transistor T1, which is a driving transistor, may be configured to control a driving current flowing through the light-emitting diode LED. The first transistor T1 may be connected to the first voltage line VDDL and the storage capacitor Cst. In an embodiment, the first transistor T1 may control a driving current flowing from the first voltage line VDDL to the light-emitting diode LED according to a voltage value stored in the storage capacitor Cst. The light-emitting diode LED may emit light having a predetermined brightness due to the driving current. A first electrode (e.g., a pixel electrode or an anode) of the light-emitting diode LED may be electrically connected to the first transistor T1, and a second electrode (e.g., an opposite electrode or a cathode) of the light-emitting diode LED may be electrically connected to the second voltage line VSSL configured to supply the second power supply voltage VSS.

FIG. 6 illustrates that the pixel circuit PC includes one switching transistor (e.g., the second transistor T2) and one capacitor (e.g., the storage capacitor Cst). However, in some embodiments, the pixel circuit PC may include two or more switching transistors and/or two or more capacitors.

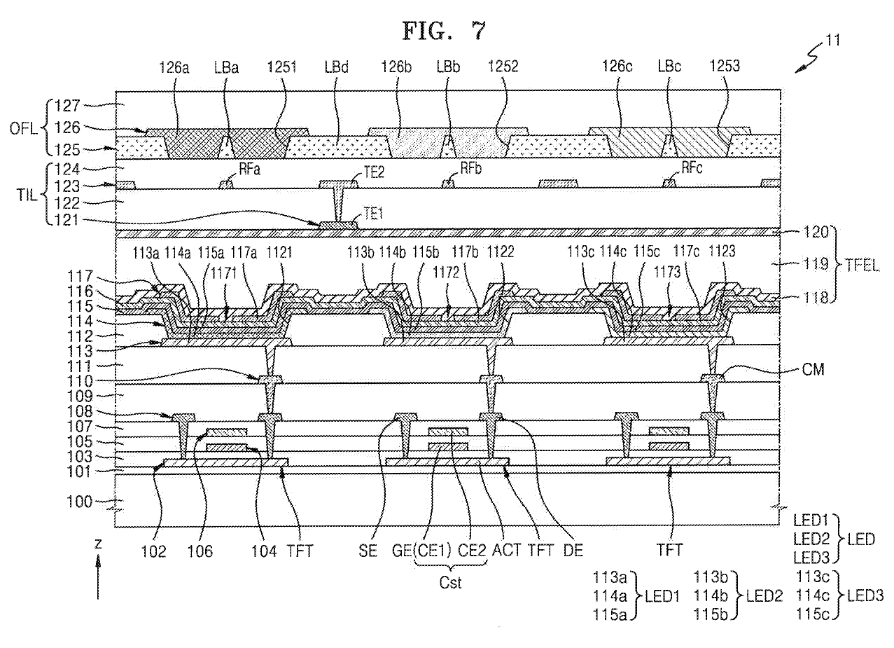

FIG. 7 is a cross-sectional view of the display panel 11 according to an embodiment. FIG. 7 may be a cross-sectional view of the display area DA of the display panel 11.

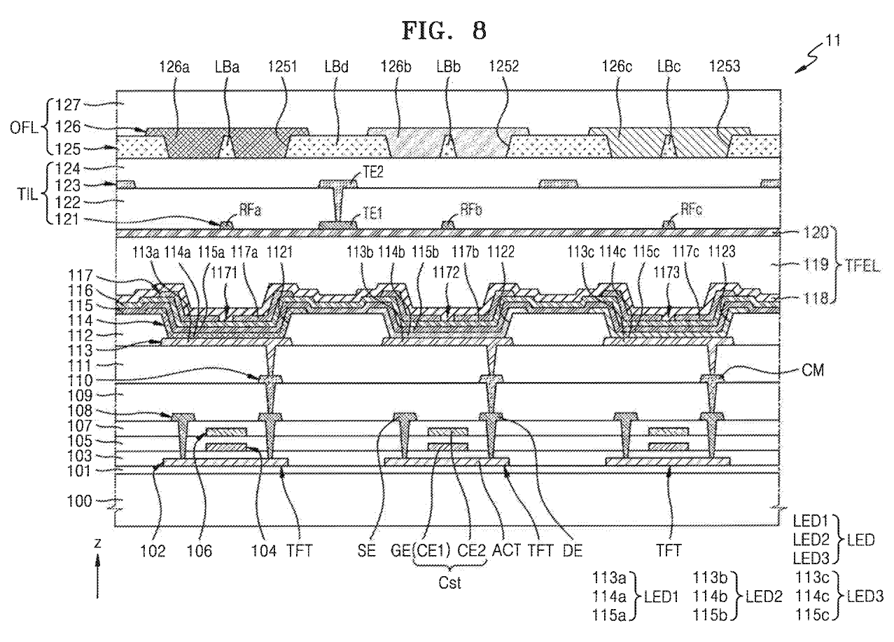

FIG. 8 is a cross-sectional view of the display panel 11 according to an embodiment. FIG. 8 may be a cross-sectional view of the display area DA of the display panel 11.

Referring to FIGS. 7 and 8, light-emitting diodes LED and thin-film transistors TFT respectively corresponding to the light-emitting diodes LED may be arranged on the substrate 100. For example, a first light-emitting diode LED1, a second light-emitting diode LED2, and a third light-emitting diode LED3 may be arranged on the substrate 100, and thin-film transistors TFT corresponding thereto may be arranged on the substrate 100. The first light-emitting diode LED1, the second light-emitting diode LED2, and the third light-emitting diode LED3 may be connected to the thin-film transistors TFT corresponding thereto.

According to an embodiment, each of the first light-emitting diode LED1, the second light-emitting diode LED2, and the third light-emitting diode LED3 may belong to separate pixels, respectively, or may belong to one pixel. In an embodiment in which the first light-emitting diode LED1, the second light-emitting diode LED2, and the third light-emitting diode LED3 belong to one pixel, each of the light-emitting diodes LED may be understood as belonging to a corresponding subpixel. The thin-film transistor TFT connected to each of the first light-emitting diode LED1, the second light-emitting diode LED2, and the third light-emitting diode LED3 may be understood as a portion of the pixel circuit PC described above with reference to FIG. 6. For example, the thin-film transistor TFT may be understood as corresponding to the first transistor T1 of FIG. 6.

A first insulating layer 101 may be disposed on the substrate 100 (e.g., disposed directly thereon in the z direction). The first insulating layer 101 may entirely cover the substrate 100. The first insulating layer 101 may play a role in flattening and protecting an upper surface of the substrate 100. The first insulating layer 101 may include an inorganic insulating material. According to an embodiment, the first insulating layer 101 may include at least one of inorganic insulating materials, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer structure or multi-layer structure of the aforementioned materials. According to an embodiment, the first insulating layer 101 may be a buffer layer.

The thin-film transistor TFT may be disposed on the first insulating layer 101 (e.g., disposed directly thereon in the z direction). The thin-film transistor TFT may include an active layer ACT, a gate electrode GE, a source electrode SE, and a drain electrode DE. The thin-film transistors TFT respectively corresponding to the first, second, and third light-emitting diodes LED1, LED2, and LED3 may be arranged on the first insulating layer 101. The thin-film transistors TFT respectively corresponding to the first, second, and third light-emitting diodes LED1, LED2, and LED3 may have similar structures to each other.

A semiconductor layer 102 may be disposed on the first insulating layer 101 (e.g., disposed directly thereon in the z direction). The semiconductor layer 102 may include an active layer ACT. The active layer ACT may be patterned to correspond to each of the thin-film transistors TFT. The active layer ACT may include a drain region overlapping a drain electrode DE, a source region overlapping a source electrode SE, and a channel region disposed between the drain region and the source region. The drain region and the source region may be regions doped with impurities (e.g., a dopant).

A second insulating layer 103 may be disposed on the semiconductor layer 102 (e.g., disposed directly thereon in the z direction). The second insulating layer 103 may include an inorganic insulating material. According to an embodiment, the second insulating layer 103 may include at least one of inorganic insulating materials, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer structure or multi-layer structure of the aforementioned materials. According to an embodiment, the second insulating layer 103 may be a first gate insulating layer. According to an embodiment, as shown in FIG. 7, the second insulating layer 103 may entirely cover the semiconductor layer 102 and the first insulating layer 101. According to an embodiment, the second insulating layer 103 may be patterned to cover only each of the active layers ACT and not cover an upper surface of the first insulating layer 101 between the active layers ACT. According to an embodiment, the second insulating layer 103 may be patterned to cover only a portion of each of the active layers ACT (e.g., a region overlapping the gate electrode GE, such as a channel region).

A storage capacitor Cst may be disposed on the second insulating layer 103. The storage capacitor Cst may include a first capacitor electrode CE1 and a second capacitor electrode CE2. The second capacitor electrode CE2 may be disposed over the first capacitor electrode CE1 (e.g., in the z direction).

A first conductive layer 104 may be disposed on the second insulating layer 103 (e.g., disposed directly thereon in the z direction). The first conductive layer 104 may include the gate electrode GE and the first capacitor electrode CE1. The gate electrode GE may be patterned to correspond to each of the thin-film transistors TFT. The gate electrode GE may overlap the channel region of the active layer ACT (e.g., in the z direction). The first capacitor electrode CE1 may be patterned to correspond to each storage capacitor Cst. According to an embodiment, the gate electrode GE and the first capacitor electrode CE1 may be provided integrally as illustrated in FIG. 7. According to an embodiment, the gate electrode GE and the first capacitor electrode CE1 may be provided individually. According to an embodiment, the first conductive layer 104 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer or multi-layer structure including the aforementioned materials.

A third insulating layer 105 may be disposed on (e.g., disposed directly thereon) the first conductive layer 104. The third insulating layer 105 may entirely cover the first conductive layer 104. The third insulating layer 105 may include an inorganic insulating material. According to an embodiment, the third insulating layer 105 may include at least one of inorganic insulating materials, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer structure or multi-layer structure of the aforementioned materials. According to an embodiment, the third insulating layer 105 may be a second gate insulating layer.

A second conductive layer 106 may be disposed on the third insulating layer 105 (e.g., disposed directly thereon in the z direction). The second conductive layer 106 may include the second capacitor electrode CE2 of each storage capacitor Cst. The second capacitor electrode CE2 may be patterned to correspond to each storage capacitor Cst. The second capacitor electrode CE2 may overlap the first capacitor electrode CE1 (e.g., in the z direction). According to an embodiment, the second conductive layer 106 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer or multi-layer structure including the aforementioned materials.

A fourth insulating layer 107 may be disposed on (e.g., disposed directly thereon) the second conductive layer 106. The fourth insulating layer 107may entirely cover the second conductive layer 106. The fourth insulating layer 107 may include an inorganic insulating material. According to an embodiment, the fourth insulating layer 107 may include at least one of inorganic insulating materials, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer structure or multi-layer structure of the aforementioned materials. According to an embodiment, the fourth insulating layer 107 may be an interlayer insulating layer.

A third conductive layer 108 may be disposed on (e.g., disposed directly thereon) the fourth insulating layer 107. The third conductive layer 108 may include the source electrode SE and the drain electrode DE of each of the thin-film transistors TFT. The source electrode SE and the drain electrode DE may be patterned to correspond to each of the thin-film transistors TFT. The source electrode SE may overlap the source region of the active layer ACT (e.g., in the z direction). The drain electrode DE may overlap the drain region of the active layer ACT (e.g., in the z direction). In an embodiment, the source electrode SE may be connected to the active layer ACT (e.g., to the source region of the active layer ACT) through an opening defined in the second, third, and fourth insulating layers 103, 105, and 107. The drain electrode DE may be connected to the active layer ACT (e.g., to the drain region of the active layer ACT) through the opening defined in the second, third, and fourth insulating layers 103, 105, and 107. According to an embodiment, the third conductive layer 108 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer or multi-layer structure including the aforementioned materials.

A fifth insulating layer 109 may be disposed on (e.g., disposed directly thereon) the third conductive layer 108. An opening overlapping with the drain electrode DE may be defined in the fifth insulating layer 109. The fifth insulating layer 109 may include an organic insulating material. According to an embodiment, the fifth insulating layer 109 may include an organic insulating material, such as a commercial polymer (such as, benzocyclobutene (BCB), polyimide, hexamethyldisiloxane (HMDSO), polymethyl methacrylate (PMMA) or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, and may have a single layer or multi-layer structure including the aforementioned materials. According to an embodiment, the fifth insulating layer 109 may be a first via layer.

A fourth conductive layer 110 may be disposed on the fifth insulating layer 109 (e.g., disposed directly thereon in the z direction). The fourth conductive layer 110 may include contact metals CM corresponding to the first, second, and third light-emitting diodes LED1, LED2, and LED3. The contact metals CM may be patterned to overlap corresponding light-emitting diodes LED (e.g., in the z direction). In an embodiment, the contact metals CM may be connected to corresponding drain electrodes DE through the openings defined in the fifth insulating layer 109. According to an embodiment, the fourth conductive layer 110 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer or multi-layer structure including the aforementioned materials.

A sixth insulating layer 111 may be disposed on the fourth conductive layer 110 (e.g., disposed directly thereon in the z direction). An opening overlapping each of the contact metals CM of the fourth conductive layer 110 (e.g., in the z direction) may be defined in the sixth insulating layer 111. The sixth insulating layer 111 may include an organic insulating material. According to an embodiment, the sixth insulating layer 111 may include an organic insulating material, such as a commercial polymer (such as, benzocyclobutene (BCB), polyimide, hexamethyldisiloxane (HMDSO), polymethyl methacrylate (PMMA) or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, and may have a single layer or multi-layer structure including the aforementioned materials. According to an embodiment, the sixth insulating layer 111 may be a second via layer.

A plurality of light-emitting diodes LED may be arranged on the sixth insulating layer 111. According to an embodiment, the first, second, and third light-emitting diodes LED1, LED2, and LED3 may be arranged on the sixth insulating layer 111 (e.g., in the z direction). Each of the plurality of light-emitting diodes LED may include a corresponding pixel electrode, a corresponding intermediate layer, and a corresponding opposite electrode. According to an embodiment, the first light-emitting diode LED1 may include a first pixel electrode 113a, a first intermediate layer 114a, and a first opposite electrode 115a. According to an embodiment, the second light-emitting diode LED2 may include a second pixel electrode 113b, a second intermediate layer 114b, and a second opposite electrode 115b. According to an embodiment, the third light-emitting diode LED3 may include a third pixel electrode 113c, a third intermediate layer 114c, and a third opposite electrode 115c. The intermediate layer of each of the plurality of light-emitting diodes LED may emit light through a current flowing in the intermediate layer due to a potential difference between the pixel electrode and the opposite electrode, and thus the light-emitting diode LED may emit light.

A fifth conductive layer 113 may be disposed on the sixth insulating layer 111 (e.g., disposed directly thereon in the z direction). In an embodiment, the fifth conductive layer 113 may include the first pixel electrode 113a, the second pixel electrode 113b, and the third pixel electrode 113c. In an embodiment, the first pixel electrode 113a, the second pixel electrode 113b, and the third pixel electrode 113c may be individually patterned to be spaced apart from each other. In an embodiment, the first pixel electrode 113a, the second pixel electrode 113b, and the third pixel electrode 113c may be connected to corresponding thin-film transistors TFT through corresponding contact metals CM and corresponding drain electrodes DE, respectively. According to an embodiment, the fifth conductive layer 113 may include conductive oxide such as indium tin oxide (ITO), indium zinc oxide (IZO), zinc oxide (ZnO), indium oxide (In₃O₃), indium gallium oxide (IGO), or aluminum zinc oxide (AZO). According to an embodiment, the fifth conductive layer 113 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound of these materials. The configuration and material of the fifth conductive layer 113 are not necessarily limited to those described above, and various modifications may be made thereto.

A pixel defining layer 112 may be disposed on (e.g., disposed directly thereon) the fifth conductive layer 113 and the sixth insulating layer 111. The pixel defining layer 112 may include a plurality of light-emitting openings overlapping with a plurality of pixel electrodes of the fifth conductive layer 113 (e.g., in the z direction). In an embodiment, the pixel defining layer 112 may cover an edge (e.g., an edge area) of each of the pixel electrodes of the fifth conductive layer 113 and may expose a central portion of the pixel electrodes of the fifth conductive layer 113. According to an embodiment, the pixel defining layer 112 may include a first light-emitting opening 1121 overlapping the first pixel electrode 113a. For example, the pixel defining layer 112 may cover an edge (or an edge area) of the first pixel electrode 113a. According to an embodiment, the pixel defining layer 112 may include a second light-emitting opening 1122 overlapping the second pixel electrode 113b. In other words, the pixel defining layer 112 may cover an edge (or an edge area) of the second pixel electrode 113b. According to an embodiment, the pixel defining layer 112 may include a third light-emitting opening 1123 overlapping the third pixel electrode 113c. In other words, the pixel defining layer 112 may cover an edge (or an edge area) of the third pixel electrode 113c.

An intermediate layer 114 may be disposed (e.g., deposited) on the pixel defining layer 112 and the fifth conductive layer 113. The intermediate layer 114 may include the first intermediate layer 114a, the second intermediate layer 114b, and the third intermediate layer 114c.

According to an embodiment, the intermediate layer 114 may include an emission layer and/or a functional layer. The emission layer may include a low-molecular weight or high-molecular weight material that emits light when a certain voltage is applied (or when a certain current flows). The functional layer may include at least one of an electron transport layer (ETL), an electron injection layer (EIL), a hole transport layer (HTL), and a hole injection layer (HIL). Each of the first intermediate layer 114a, the second intermediate layer 114b, and the third intermediate layer 114c may include an emission layer and/or a functional layer.

According to an embodiment, the emission layers respectively included in the first intermediate layer 114a, the second intermediate layer 114b, and the third intermediate layer 114c may include different materials from each other. For example, the emission layers respectively included in the first intermediate layer 114a, the second intermediate layer 114b, and the third intermediate layer 114c may emit light beams in different wavelength bands (e.g., colors) from each other. According to an embodiment, the emission layer included in the first intermediate layer 114a may emit red light when a current flows. According to an embodiment, the emission layer included in the second intermediate layer 114b may emit green light when a current flows. According to an embodiment, the emission layer included in the third intermediate layer 114c may emit blue light when a current flows.

The first intermediate layer 114a may overlap the first pixel electrode 113a. According to an embodiment, a portion (e.g., a first portion) of the first intermediate layer 114a may be disposed within the first light-emitting opening 1121 of the pixel defining layer 112 and may be in direct contact with the first pixel electrode 113a. According to an embodiment, another portion (e.g., a second portion) of the first intermediate layer 114a may be disposed on the pixel defining layer 112. According to an embodiment, the first portion and the second portion of the first intermediate layer 114a may be connected to each other. For example, the first intermediate layer 114a may cover an edge of the pixel defining layer 112 defining the first light-emitting opening 1121. According to an embodiment, the first intermediate layer 114a may be entirely disposed within the first light-emitting opening 1121. According to an embodiment, the emission layer of the first intermediate layer 114a may be disposed within the first light-emitting opening 1121, and the functional layer of the first intermediate layer 114a may extend to outside the first light-emitting opening 1121.

The second intermediate layer 114b may overlap the second pixel electrode 113b. According to an embodiment, a portion (e.g., a first portion) of the second intermediate layer 114b may be disposed within the second light-emitting opening 1122 of the pixel defining layer 112 and may be in direct contact with the second pixel electrode 113b. According to an embodiment, another portion (e.g., a second portion) of the second intermediate layer 114b may be disposed on the pixel defining layer 112. According to an embodiment, the first portion and the second portion of the second intermediate layer 114b may be connected to each other. For example, the second intermediate layer 114b may cover an edge of the pixel defining layer 112 defining the second light-emitting opening 1122. According to an embodiment, the second intermediate layer 114b may be entirely disposed within the second light-emitting opening 1122. According to an embodiment, the emission layer of the second intermediate layer 114b may be disposed within the second light-emitting opening 1122, and the functional layer of the second intermediate layer 114b may extend to outside the second light-emitting opening 1122.

The third intermediate layer 114c may overlap the third pixel electrode 113c. According to an embodiment, a portion (e.g., a first portion) of the third intermediate layer 114c may be disposed within the third light-emitting opening 1123 of the pixel defining layer 112 and may be in direct contact with the third pixel electrode 113c. According to an embodiment, another portion (e.g., a second portion) of the third intermediate layer 114c may be disposed on the pixel defining layer 112. According to an embodiment, the first portion and the second portion of the third intermediate layer 114c may be connected to each other. For example, the third intermediate layer 114c may cover an edge of the pixel defining layer 112 defining the third light-emitting opening 1123. According to an embodiment, the third intermediate layer 114c may be entirely disposed within the third light-emitting opening 1123. According to an embodiment, the emission layer of the third intermediate layer 114c may be disposed within the third light-emitting opening 1123, and the functional layer of the third intermediate layer 114c may extend to outside the third light-emitting opening 1123.

An opposite electrode 115 may be disposed on the intermediate layer 114. In an embodiment, the opposite electrode 115 may be formed integrally over (e.g., commonly disposed over) the first, second, and third light-emitting diodes LED1, LED2, and LED3. The opposite electrode 115 may cover the intermediate layer 114. A portion of the opposite electrode 115 that overlaps the first intermediate layer 114a may be considered as the first opposite electrode 115a. According to an embodiment, the first opposite electrode 115a may cover the first intermediate layer 114a. A portion of the opposite electrode 115 that overlaps the second intermediate layer 114b may be considered as the second opposite electrode 115b. According to an embodiment, the second opposite electrode 115b may cover the second intermediate layer 114b. A portion of the opposite electrode 115 that overlaps the third intermediate layer 114c may be considered as the third opposite electrode 115c. According to an embodiment, the third opposite electrode 115c may cover the third intermediate layer 114c.

The opposite electrode 115 may include a conductive material. According to an embodiment, the opposite electrode 115 may include a transparent layer (or a semi-transparent layer) including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the opposite electrode 115 may further include a layer including a material, such as indium tin oxide (ITO), indium zinc oxide (IZO), zinc oxide (ZnO), or indium oxide (In₂O₃), on the transparent layer (or the semi-transparent layer) including any of the aforementioned materials.

A capping layer 116 may be disposed on the light-emitting diode LED. The capping layer 116 may be disposed on (e.g., disposed directly thereon) the opposite electrode 115. The capping layer 116 may cover the opposite electrode 115. According to an embodiment, the capping layer 116 may increase the luminous efficiency of the light-emitting diode LED according to the principle of constructive interference.

In an embodiment, the capping layer 116 may be an organic capping layer including an organic material, an inorganic capping layer including an inorganic material, or a complex capping layer including an organic material and an inorganic material. According to an embodiment, the capping layer 116 may include a carbocyclic compound, a heterocyclic compound, an amine group-containing compound, porphine derivatives, phthalocyanine derivatives, naphthalocyanine derivatives, an alkali metal complex, an alkaline earth metal complex, or any combination thereof.

An absorption layer 117 may be disposed on (e.g., disposed directly thereon) the capping layer 116. In an embodiment, the absorption layer 117 may include a first absorption pattern 117a, a second absorption pattern 117b, and a third absorption pattern 117c. The first absorption pattern 117a may overlap the first light-emitting diode LED1 (e.g., in the z direction). According to an embodiment, the first absorption pattern 117a may be disposed on the first light-emitting diode LED1 and may overlap the first pixel electrode 113a (e.g., in a plan view, such as in the z direction). The second absorption pattern 117b may overlap the second light-emitting diode LED2 (e.g., in a plan view, such as in the z direction). According to an embodiment, the second absorption pattern 117b may be disposed on the second light-emitting diode LED2 and may overlap the second pixel electrode 113b (e.g., in a plan view, such as in the z direction). The third absorption pattern 117c may overlap the third light-emitting diode LED3. According to an embodiment, the third absorption pattern 117c may be disposed on the third light-emitting diode LED3 and may overlap the third pixel electrode 113c (e.g., in a plan view, such as in the z direction).

The absorption layer 117 may absorb external light incident onto the light-emitting diode LED and thereby reduce external light being reflected by a pixel electrode (e.g., the fifth conductive layer 113) of the light-emitting diode LED which would be visible to a user. For example, the first absorption pattern 117a may absorb external light incident onto the first light-emitting diode LED1 to thereby reduce external light being reflected by the first pixel electrode 113a of the first light-emitting diode LED1 which would be visible to a user. At least a portion of the light emitted by the first light-emitting diode LED1, for example, by the emission layer of the first intermediate layer 114a, may pass through the first absorption pattern 117a. This feature is also similarly applicable to the second absorption pattern 117b, the second light-emitting diode LED2, the third absorption pattern 117c, and the third light-emitting diode LED3.

To achieve the above-mentioned objective, the absorption layer 117 may include a material having certain characteristics. According to an embodiment, the absorption layer 117 may include a material having a refractive index greater than or equal to about 1.0. According to an embodiment, the absorption layer 117 may include a material having an absorption coefficient greater than or equal to about 0.5. According to an embodiment, the absorption layer 117 may include a material capable of thermal deposition. According to an embodiment, the absorption layer 117 may include an inorganic material. According to an embodiment, the absorption layer 117 may include a metal. According to an embodiment, the absorption layer 117 may include bismuth (Bi). According to an embodiment, the absorption layer 117 may include ytterbium (Yb).

A first opening 1171 may be defined in the first absorption pattern 117a. For example, the first opening 1171 may be formed in the first absorption pattern 117a. According to an embodiment, the first opening 1171 may be disposed in a center portion of the first absorption pattern 117a (e.g., in a plan view). According to an embodiment, the first opening 1171 may overlap a center portion of the first pixel electrode 113a (e.g., in the z direction). A portion of the light emitted by the first light-emitting diode LED1, for example, by the emission layer of the first intermediate layer 114a, may pass through the first opening 1171 of the first absorption pattern 117a. However, embodiments of the present disclosure are not necessarily limited thereto and the first opening 1171 may overlap another portion of the first pixel electrode 113a other than the center portion in some embodiments and light emitted by the first light-emitting diode LED1 may pass through such portion of the first pixel electrode 113a. The light may be reflected by a first reflection pattern RFa that is to be described later, and may be re-incident towards the first light-emitting diode LED1. The light incident again towards the first light-emitting diode LED1 may be reflected by the first pixel electrode 113a and generally travel in a +z direction (e.g., towards the user). Accordingly, a portion of the light emitted by the first light-emitting diode LED1 may be recycled, leading to an increase in the efficiency of the display panel 11.

A second opening 1172 may be defined in the second absorption pattern 117b. For example, the second opening 1172 may be formed in the second absorption pattern 117b. According to an embodiment, the second opening 1172 may be disposed in a center portion of the second absorption pattern 117b (e.g., in a plan view). According to an embodiment, the second opening 1172 may overlap the center portion of the second pixel electrode 113b (e.g., in the z direction). A portion of the light emitted by the second light-emitting diode LED2, for example, by the emission layer of the second intermediate layer 114b, may pass through the second opening 1172 of the second absorption pattern 117b. However, embodiments of the present disclosure are not necessarily limited thereto and the second opening 1172 may overlap another portion of the second pixel electrode 113b other than the center portion in some embodiments and light emitted by the second light-emitting diode LED2 may pass through such portion of the second pixel electrode 113b. The light may be reflected by a second reflection pattern RFb that is to be described later, and may be re-incident towards the second light-emitting diode LED2. The light incident again towards the second light-emitting diode LED2 may be reflected by the second pixel electrode 113b and generally travel in the +z direction (e.g., towards the user). Accordingly, a portion of the light emitted by the second light-emitting diode LED2 may be recycled, leading to an increase in the efficiency of the display panel 11.

A third opening 1173 may be defined in the third absorption pattern 117c. For example, the third opening 1173 may be formed in the third absorption pattern 117c. According to an embodiment, the third opening 1173 may be disposed in a center portion of the third absorption pattern 117c (e.g., in a plan view). According to an embodiment, the third opening 1173 may overlap a center portion of the third pixel electrode 113c (e.g., in the z direction). A portion of the light emitted by the third light-emitting diode LED3, for example, by the emission layer of the third intermediate layer 114c, may pass through the third opening 1173 of the third absorption pattern 117c. However, embodiments of the present disclosure are not necessarily limited thereto and the third opening 1173 may overlap another portion of the third pixel electrode 113c other than the center portion in some embodiments and light emitted by the third light-emitting diode LED3 may pass through such portion of the third pixel electrode 113c. The light may be reflected by a third reflection pattern RFc that is to be described later, and may be re-incident towards the third light-emitting diode LED3. The light incident again towards the third light-emitting diode LED3 may be reflected by the third pixel electrode 113c and generally travel in the +z direction (e.g., towards the user). Accordingly, a portion of the light emitted by the third light-emitting diode LED3 may be recycled, leading to an increase in the efficiency of the display panel 11.

For example, the absorption layer 117 may reduce the external light being reflected by the fifth conductive layer 113 and being visible to the user by absorbing external light, and, at the same time, recycling the light emitted by a corresponding light-emitting diode LED by including the first, second, and third openings 1171, 1172, and 1173. Accordingly, the absorption layer 117 may increase the efficiency of the display panel 11 and may increase the display quality of the display panel.

A thin-film encapsulation layer TFEL may be disposed on (e.g., disposed directly thereon) the absorption layer 117. The thin-film encapsulation layer TFEL may entirely cover the absorption layer 117, the capping layer 116, and the light-emitting diode LED. The thin-film encapsulation layer TFEL may include at least one organic encapsulation layer and at least one inorganic encapsulation layer. According to an embodiment, the thin-film encapsulation layer TFEL may include a first inorganic encapsulation layer 118, a second inorganic encapsulation layer 120, and an organic encapsulation layer 119 between the first and second inorganic encapsulation layers 118 and 120 (e.g., in the z direction). According to an embodiment, the first inorganic encapsulation layer 118 may entirely cover the absorption layer 117. According to an embodiment, the organic encapsulation layer 119 may be included as a planarization layer.

According to an embodiment, the first inorganic encapsulation layer 118 and the second inorganic encapsulation layer 120 may include at least one of inorganic insulating materials, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The organic encapsulation layer 119 may include an organic insulating material. According to an embodiment, the organic encapsulation layer 119 may include a polymer-based material. Examples of the polymer-based material may include a silicon-based resin, an acryl-based resin, an epoxy-based resin, polyimide, and polyethylene. However, embodiments of the present disclosure are not necessarily limited to the thin film encapsulation layer TFEL having the above-described structure, and the numbers of at least one inorganic encapsulation layer and at least one organic encapsulation layer and a stacking order thereof may vary.

In an embodiment, a touch input layer TIL may be disposed directly on the thin-film encapsulation layer TFEL (e.g., in the z direction). The touch input layer TIL may detect an external input, for example, a touch from an object such as a finger or a pen, so that the display panel 11 may obtain coordinate information corresponding to a location of contact. The touch input layer TIL may include a touch electrode and signal lines connected to the touch electrode. The touch input layer TIL may sense the external input according to a mutual cap method and/or a self cap method.

In an embodiment, the touch input layer TIL may include a first touch conductive layer 121, a first touch insulating layer 122, a second touch conductive layer 123, and a second touch insulating layer 124. The first touch insulating layer 122 may be disposed on (e.g., disposed directly thereon) the first touch conductive layer 121 and may entirely cover the first touch conductive layer 121. According to an embodiment, the first touch insulating layer 122 may be included as a planarization layer. The second touch conductive layer 123 may be disposed on the first touch insulating layer 122 (e.g., disposed directly thereon in the z direction). The second touch insulating layer 124 may be disposed on (e.g., disposed directly thereon) the second touch conductive layer 123 and may entirely cover the second touch conductive layer 123. According to an embodiment, the second touch insulating layer 124 may be included as a planarization layer. According to an embodiment, the first touch conductive layer 121 and the second touch conductive layer 123 may be arranged in a specific pattern. According to an embodiment, the first touch conductive layer 121 and/or the second touch conductive layer 123 may include a metal layer, and the metal layer may include Mo, Ag, Ti, Cu, Al, or an alloy thereof. According to an embodiment, the first touch conductive layer 121 and/or the second touch conductive layer 123 may include a transparent conductive layer, and the transparent conductive layer may include a transparent conductive oxide (such as, ITO, IZO, ZnO, indium tin zinc oxide (ITZO)), a conductive polymer (such as, PEDOT), a metal nanowire, carbon nanotubes, or graphene.

In an embodiment, an additional insulating layer (e.g., an inorganic insulating layer) may be disposed between the first touch conductive layer 121 and the second inorganic encapsulation layer 120 (e.g., in the z direction).

The first touch conductive layer 121 may include a first touch electrode TE1. The second touch conductive layer 123 may include a second touch electrode TE2. In an embodiment, the second touch electrode TE2 may be connected to the first touch electrode TE1 through a contact hole defined in the first touch insulating layer 122. According to an embodiment, the second touch electrode TE2 may be a sensing electrode, and the first touch electrode TE1 may be a bridge electrode.

According to an embodiment, referring to FIG. 7, the second touch conductive layer 123 may include the first reflection pattern RFa, the second reflection pattern RFb, and the third reflection pattern RFc. For example, in an embodiment the first reflection pattern RFa, the second reflection pattern RFb, and the third reflection pattern RFc may be arranged on the same layer as a layer on which the second touch electrode TE2 is disposed. For example, each of the first reflection pattern RFa, the second reflection pattern RFb, and the third reflection pattern RFc may be disposed directly on an upper surface of the first touch insulating layer 122. The first reflection pattern RFa may overlap the first opening 1171 of the first absorption pattern 117a (e.g., in the z direction). The second reflection pattern RFb may overlap the second opening 1172 of the second absorption pattern 117b (e.g., in the z direction). The third reflection pattern RFc may overlap the third opening 1173 of the third absorption pattern 117c (e.g., in the z direction).

According to an embodiment, referring to FIG. 8, the first reflection pattern RFa, the second reflection pattern RFb, and the third reflection pattern RFc may be arranged in the first touch conductive layer 121. For example, the first reflection pattern RFa, the second reflection pattern RFb, and the third reflection pattern RFc may be arranged on the same layer as a layer on which the first touch electrode TE1 is disposed. For example, each of the first reflection pattern RFa, the second reflection pattern RFb, and the third reflection pattern RFc may be disposed directly on an upper surface of the second inorganic encapsulation layer 120.

The first reflection pattern RFa may reflect, towards the first light-emitting diode LED1, for example, the first pixel electrode 113a, light emitted by the first light-emitting diode LED1, for example, by the emission layer of the first intermediate layer 114a and transmitted by the first opening 1171 of the first absorption pattern 117a. The second reflection pattern RFb may reflect, towards the second light-emitting diode LED2, for example, the second pixel electrode 113b, light emitted by the second light-emitting diode LED2, for example, by the emission layer of the second intermediate layer 114b and transmitted by the second opening 1172 of the second absorption pattern 117b. The third reflection pattern RFc may reflect, towards the third light-emitting diode LED3, for example, the third pixel electrode 113c, light emitted by the third light-emitting diode LED3, for example, by the emission layer of the third intermediate layer 114c and transmitted by the third opening 1173 of the third absorption pattern 117c.

An optical functional layer OFL may be disposed on the touch input layer TIL (e.g., disposed directly thereon in the z direction). According to an embodiment, the optical functional layer OFL may include a light-blocking layer 125, a color filter layer 126, and a reflection control layer 127.

The light-blocking layer 125 may be disposed on the second touch insulating layer 124 (e.g., disposed directly thereon in the z direction). The light-blocking layer 125 may include a light-blocking material. For example, in an embodiment the light-blocking layer 125 may include a black dye.

In an embodiment, the light-blocking layer 125 may include a first light-blocking pattern LBa, a second light-blocking pattern LBb, a third light-blocking pattern LBc, and a fourth light-blocking pattern LBd. The first light-blocking pattern LBa may overlap the first opening 1171 of the first absorption pattern 117a and the first reflection pattern RFa (e.g., in the z direction). The second light-blocking pattern LBb may overlap the second opening 1172 of the second absorption pattern 117b and the second reflection pattern RFb (e.g., in the z direction). The third light-blocking pattern LBc may overlap the third opening 1173 of the third absorption pattern 117c and the third reflection pattern RFc (e.g., in the z direction). The fourth light-blocking pattern LBd may overlap the pixel defining layer 112 (e.g., in the z direction).

The first light-blocking pattern LBa may block external light from reaching the first reflection pattern RFa. Accordingly, the external light may be prevented from being reflected by the first reflection pattern RFa and being recognized by the user which would result in a decrease in the quality of the displayed images. The second light-blocking pattern LBb may block external light from reaching the second reflection pattern RFb. Accordingly, the external light may be prevented from being reflected by the second reflection pattern RFb and being recognized by the user which would result in a decrease in the quality of the displayed images. The third light-blocking pattern LBc may block external light from reaching the third reflection pattern RFc. Accordingly, the external light may be prevented from being reflected by the third reflection pattern RFc and being recognized by the user which would result in a decrease in the quality of the displayed images.

The light-blocking layer 125 may include holes that overlap the light-emitting diodes LED, respectively. The light-blocking layer 125 may include a first hole 1251 that overlaps the first light-emitting diode LED1 (e.g., in the z direction). The first hole 1251 of the light-blocking layer 125 may overlap the first light-emitting opening 1121 of the pixel defining layer 112 (e.g., in the z direction). The first light-blocking pattern LBa may be disposed within the first hole 1251. The light-blocking layer 125 may include a second hole 1252 that overlaps the second light-emitting diode LED2 (e.g., in the z direction). The second hole 1252 of the light-blocking layer 125 may overlap the second light-emitting opening 1122 of the pixel defining layer 112 (e.g., in the z direction). The second light-blocking pattern LBb may be disposed within the second hole 1252. The light-blocking layer 125 may include a third hole 1253 that overlaps the third light-emitting diode LED3 (e.g., in the z direction). The third hole 1253 of the light-blocking layer 125 may overlap the third light-emitting opening 1123 of the pixel defining layer 112 (e.g., in the z direction). The third light-blocking pattern LBc may be disposed within the third hole 1253. The fourth light-blocking pattern LBd may be understood as a portion of the light-blocking layer 125 that defines the holes of the light-blocking layer 125 (e.g., the first, second, and third holes 1251, 1252, and 1253).

According to an embodiment, the second touch insulating layer 124 may be omitted, and the light-blocking layer 125 may be disposed directly on the second touch conductive layer 123 (e.g., in the z direction). In this embodiment, the first light-blocking pattern LBa may cover the first reflection pattern RFa, the second light-blocking pattern LBb may cover the second reflection pattern RFb, the third light-blocking pattern LBc may cover the third reflection pattern RFc, and the fourth light-blocking pattern LBd may cover the second touch electrode TE2.

The color filter layer 126 may be disposed on (e.g., disposed directly thereon) the light-blocking layer 125. In an embodiment, the color filter layer 126 may include a first color filter 126a, a second color filter 126b, and a third color filter 126c.

The first color filter 126a may overlap the first light-emitting diode LED1 (e.g., in the z direction). A portion of the first color filter 126a may be disposed within the first hole 1251 of the light-blocking layer 125. Another portion of the first color filter 126a may be disposed on an upper surface of the fourth light-blocking pattern LBd defining the first hole 1251. The first color filter 126a may cover the first light-blocking pattern LBa. For example, the first color filter 126a may cover the first light-blocking pattern LBa disposed within the first hole 1251 while filling the entire first hole 1251.

The second color filter 126b may overlap the second light-emitting diode LED2 (e.g., in the z direction). A portion of the second color filter 126b may be disposed within the second hole 1252 of the light-blocking layer 125. Another portion of the second color filter 126b may be disposed on the upper surface of the fourth light-blocking pattern LBd defining the second hole 1252. The second color filter 126b may cover the second light-blocking pattern LBb. For example, the second color filter 126b may cover the second light-blocking pattern LBb disposed within the second hole 1252 while filling the entire second hole 1252.

The third color filter 126c may overlap the third light-emitting diode LED3 (e.g., in the z direction). A portion of the third color filter 126c may be disposed within the third hole 1253 of the light-blocking layer 125. Another portion of the third color filter 126c may be disposed on the upper surface of the fourth light-blocking pattern LBd defining the third hole 1253. The third color filter 126c may cover the third light-blocking pattern LBc. For example, the third color filter 126c may cover the third light-blocking pattern LBc disposed within the third hole 1253 while filling the entire third hole 1253.

FIG. 7 illustrates an embodiment in which color filters are spaced apart from each other on the upper surface of the fourth light-blocking pattern LBd, but embodiments of the present disclosure are not necessarily limited thereto. According to an embodiment, two or more selected from the first color filter 126a, the second color filter 126b, and the third color filter 126c may overlap each other (e.g., in the z direction) on the upper surface of the fourth light-blocking pattern LBd.

The first color filter 126a, the second color filter 126b, and the third color filter 126c may transmit light beams of corresponding colors (e.g., wavelength bands), respectively. According to an embodiment, the first color filter 126a may transmit light of a color (e.g., a wavelength band) emitted by the first light-emitting diode LED1. According to an embodiment, red light may be emitted by the first light-emitting diode LED1, and the first color filter 126a may transmit the red light. According to an embodiment, the second color filter 126b may transmit light of a color (e.g., a wavelength band) emitted by the second light-emitting diode LED2. According to an embodiment, green light may be emitted by the second light-emitting diode LED2, and the second color filter 126b may transmit the green light. According to an embodiment, the third color filter 126c may transmit light of a color (e.g., a wavelength band) emitted by the third light-emitting diode LED3. According to an embodiment, blue light may be emitted by the third light-emitting diode LED3, and the third color filter 126c may transmit the blue light.

The reflection control layer 127 may be disposed on (e.g., disposed directly thereon) the color filter layer 126. The reflection control layer 127 may be included as an overcoat layer that entirely covers the first color filter 126a, the second color filter 126b, and the third color filter 126c. According to an embodiment, the reflection control layer 127 may absorb light having a different wavelength band than light emitted by the first light-emitting diode LED1, the second light-emitting diode LED2, or the third light-emitting diode LED3. According to an embodiment, the reflection control layer 127 may absorb light in a wavelength band in a range of about 480 nanometers (nm) to about 510 nanometers (nm). According to an embodiment, the reflection control layer 127 may absorb light in a wavelength band in a range of about 580 nm to about 610 nm. Accordingly, the reflection control layer 127 may transmit light emitted by the light-emitting diode LED and transmitted by the color filter layer 126, and may absorb external light corresponding to a different wavelength band from that of the transmitted light. Therefore, the reflection control layer 127 may reduce light that may be introduced into and reflected by the display panel 11.

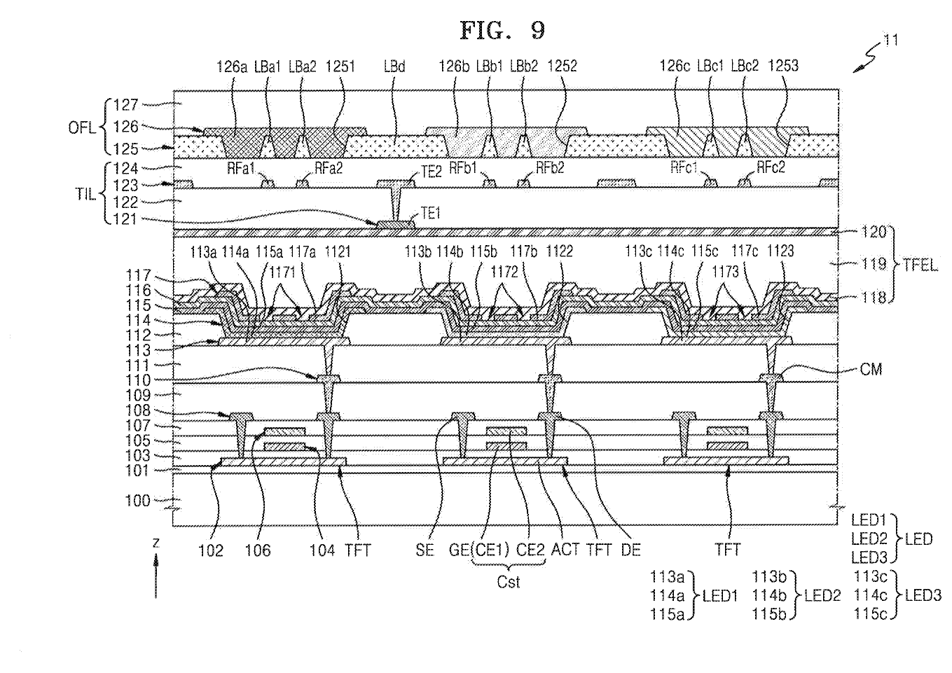

FIG. 9 is a cross-sectional view of the display panel 11 according to an embodiment. FIG. 9 may be a cross-sectional view of the display area DA of the display panel 11.

Referring to FIG. 9, a plurality of openings may be defined in each absorption pattern. According to an embodiment, a plurality of first openings 1171 may be defined in the first absorption pattern 117a. According to an embodiment, a plurality of second openings 1172 may be defined in the second absorption pattern 117b. According to an embodiment, a plurality of third openings 1173 may be defined in the third absorption pattern 117c. While an embodiment shown in FIG. 9 shows the plurality of openings formed in the first to third absorption patterns 117a to 117c being two, embodiments of the present disclosure are not necessarily limited thereto and three or more openings may be formed in the first to third absorption patterns 117a to 117c.

The second touch conductive layer 123 may be provided with a plurality of reflection patterns corresponding to each absorption pattern. According to an embodiment, the second touch conductive layer 123 may be provided with a 1-1 reflection pattern RFa1 and a 1-2 reflection pattern RFa2 that overlap the plurality of first openings 1171 of the first absorption pattern 117a, respectively (e.g., in the z direction). According to an embodiment, the second touch conductive layer 123 may be provided with a 2-1 reflection pattern RFb1 and a 2-2 reflection pattern RFb2 that overlap the plurality of second openings 1172 of the second absorption pattern 117b, respectively (e.g., in the z direction). According to an embodiment, the second touch conductive layer 123 may be provided with a 3-1 reflection pattern RFc1 and a 3-2 reflection pattern RFc2 that overlap the plurality of third openings 1173 of the third absorption pattern 117c, respectively (e.g., in the z direction). As described above, in some embodiments these reflective patterns may be included in the first touch conductive layer 121 instead of the second touch conductive layer 123 as shown in FIG. 9.

The light-blocking layer 125 may be provided with a plurality of light-blocking patterns corresponding to each absorption pattern. According to an embodiment, the light-blocking layer 125 may be provided with a 1-1 light-blocking pattern LBa1 and a 1-2 light-blocking pattern LBa2 that overlap the plurality of first openings 1171 of the first absorption pattern 117a, respectively (e.g., in the z direction). The 1-1 light-blocking pattern LBa1 may overlap the 1-1 reflection pattern RFa1, and the 1-2 light-blocking pattern LBa2 may overlap the 1-2 reflection pattern RFa2 (e.g., in the z direction). According to an embodiment, the light-blocking layer 125 may be provided with a 2-1 light-blocking pattern LBb1 and a 2-2 light-blocking pattern LBb2 that overlap the plurality of second openings 1172 of the second absorption pattern 117b, respectively (e.g., in the z direction). The 2-1 light-blocking pattern LBb1 may overlap the 2-1 reflection pattern RFb1, and the 2-2 light-blocking pattern LBb2 may overlap the 2-2 reflection pattern RFb2 (e.g., in the z direction). According to an embodiment, the light-blocking layer 125 may be provided with a 3-1 light-blocking pattern LBc1 and a 3-2 light-blocking pattern LBc2 that overlap the plurality of third openings 1173 of the third absorption pattern 117c, respectively (e.g., in the z direction). The 3-1 light-blocking pattern LBc1 may overlap the 3-1 reflection pattern RFc1, and the 3-2 light-blocking pattern LBc2 may overlap the 3-2 reflection pattern RFc2 (e.g., in the z direction).

However, embodiments of the present disclosure are not necessarily limited to only a case where two openings are included in one absorption pattern as illustrated in FIG. 9, and the number of openings may vary. The present disclosure is not necessarily limited to only a case where the same number of openings are included in each absorption pattern as illustrated in FIG. 9, and the number of openings included in each absorption pattern may be different from each other.

An effect achieved by a plurality of openings of each absorption pattern and reflection patterns and light-blocking patterns corresponding to the plurality of openings has been described above with reference to FIGS. 7 and 8 and a repeated description will be omitted for economy of explanation.

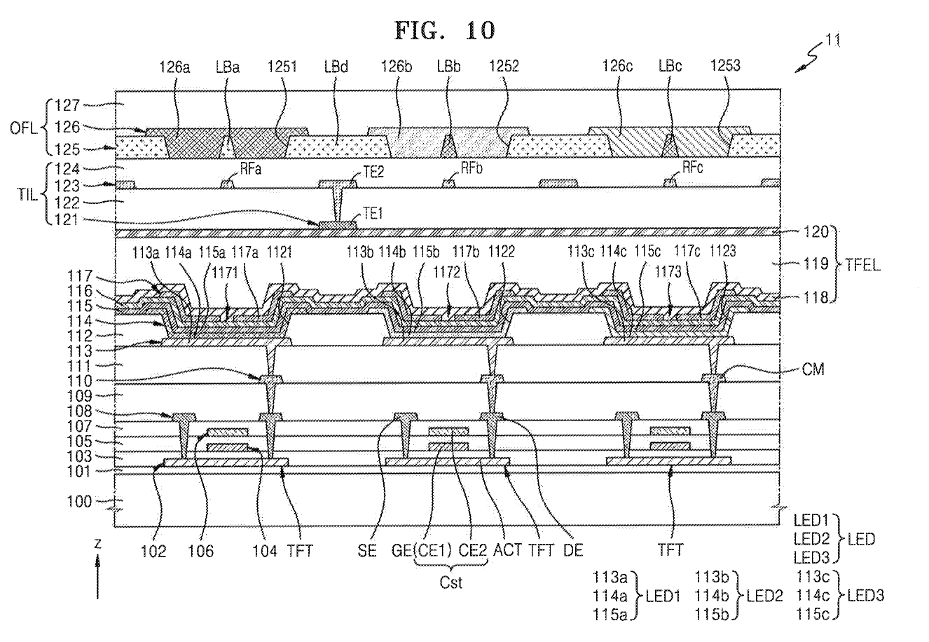

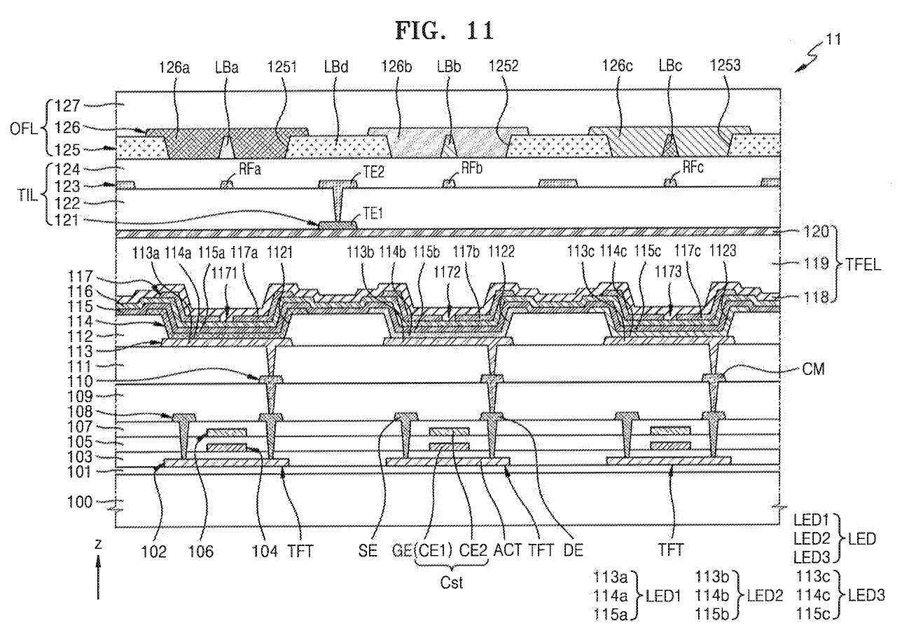

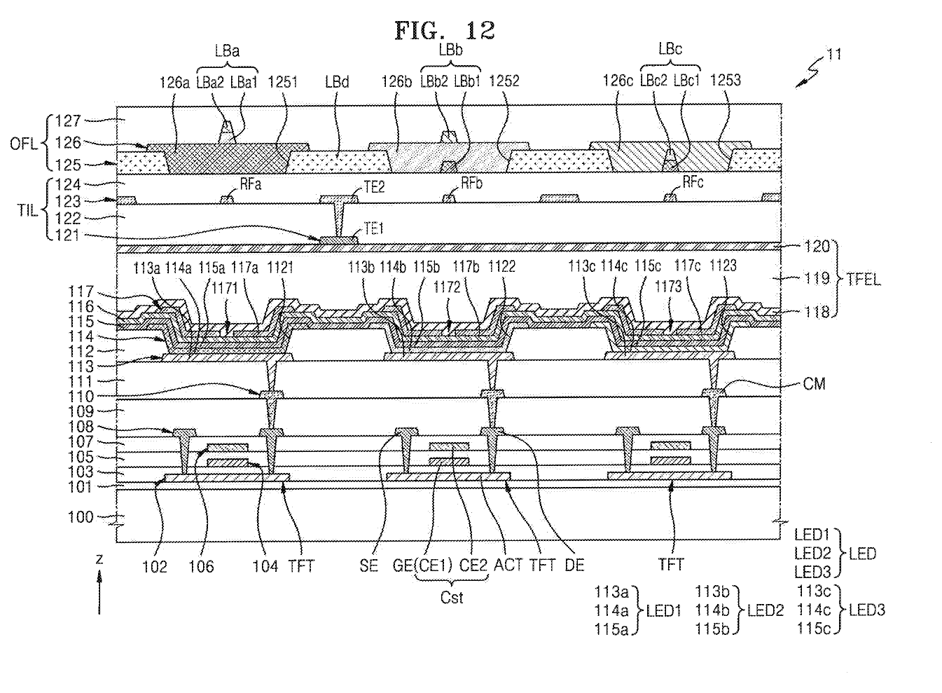

FIG. 10 is a cross-sectional view of the display panel 11 according to an embodiment. FIG. 11 is a cross-sectional view of the display panel 11 according to an embodiment. FIG. 12 is a cross-sectional view of the display panel 11 according to an embodiment. FIGS. 10 through 12 may be cross-sectional views of the display area DA of the display panel 11.

Referring to FIG. 10, in an embodiment some of the light-blocking patterns may be portions of the light-blocking layer 125, and the others may be portions of the color filter layer 126.

According to an embodiment, the first light-blocking pattern LBa may be a portion of the light-blocking layer 125. According to an embodiment, the second light-blocking pattern LBb may be a portion of the color filter layer 126. For example, in an embodiment the second light-blocking pattern LBb may include the same material as the first color filter 126a. According to an embodiment, the third light-blocking pattern LBc may be a portion of the color filter layer 126. For example, in an embodiment the third light-blocking pattern LBc may include the same material as the first color filter 126a.

The first color filter 126a and the second color filter 126b may transmit light beams of different colors from each other. Accordingly, the second light-blocking pattern LBb and the second color filter 126b may transmit light beams of different colors from each other. Thus, light transmitted by the second color filter 126b among the external light may not pass through the second light-blocking pattern LBb. Accordingly, the second light-blocking pattern LBb may perform a role of blocking light.

The first color filter 126a and the third color filter 126c may transmit light beams of different colors from each other. Accordingly, the third light-blocking pattern LBc and the third color filter 126c may transmit light beams of different colors from each other. Thus, light transmitted by the third color filter 126c among the external light may not pass through the third light-blocking pattern LBc. Accordingly, the third light-blocking pattern LBc may perform a role of blocking light.

In an embodiment, due to inclusion of a light-blocking pattern including a material that transmits light of a different wavelength band (e.g., color) than the light transmitted by each color filter, an effect similar to that in a case where a light-blocking pattern is a portion of the light-blocking layer 125 may be obtained. FIG. 10 illustrates an embodiment in which the first light-blocking pattern LBa is a portion of the light-blocking layer 125 and the second and third light-blocking patterns LBb and LBc are portions of the color filter layer 126, but embodiments of the present disclosure are not necessarily limited thereto. According to an embodiment, the second light-blocking pattern LBb and/or the third light-blocking pattern LBc may be portions of the light-blocking layer 125, and the first light-blocking pattern LBa is a portion of the color filter layer 126. According to an embodiment, all of the first, second, and third light-blocking patterns LBa, LBb, and LBc may be portions of the color filter layer 126.

For example, referring to FIG. 11, in an embodiment the first light-blocking pattern LBa, the second light-blocking pattern LBb, and the third light-blocking pattern LBc may all be portions of the color filter layer 126.

According to an embodiment as shown in FIG. 11, the first light-blocking pattern LBa may include the same material as the second color filter 126b. According to an embodiment, the second light-blocking pattern LBb may include the same material as the third color filter 126c. According to an embodiment, the third light-blocking pattern LBc may include the same material as the first color filter 126a.

FIG. 11 illustrates an embodiment in which the first, second, and third light-blocking patterns LBa, LBb, and LBc are arranged below color filters corresponding thereto, but embodiments of the present disclosure are not necessarily limited thereto. According to an embodiment, some of the first, second, and third light-blocking patterns LBa, LBb, and LBc may be arranged over color filters corresponding thereto (e.g., in the z direction) according to the stacking order of the first color filter 126a, the second color filter 126b, and the third color filter 126c.

For example, referring to FIG. 12, the color filter layer 126 may be stacked (e.g., in the z direction) in the order of the first color filter 126a, the second color filter 126b, and the third color filter 126c.

In an embodiment, the first light-blocking pattern LBa may include a 1-1 light-blocking pattern LBa1 including the same material as the second color filter 126b and a 1-2 light-blocking pattern LBa2 including the same material as the third color filter 126c. The 1-1 light-blocking pattern LBa1 may be disposed directly on an upper surface of the first color filter 126a. The 1-2 light-blocking pattern LBa2 may be disposed directly on an upper surface of the 1-1 light-blocking pattern LBa1. According to an embodiment, the 1-1 light-blocking pattern LBa1 may be formed simultaneously with the second color filter 126b. According to an embodiment, the 1-2 light-blocking pattern LBa2 may be formed simultaneously with the third color filter 126c. According to the present embodiment, since the color filters may be formed in the order of the first color filter 126a, the second color filter 126b, and the third color filter 126c, the 1-1 light-blocking pattern LBa1 and the 1-2 light-blocking pattern LBa2 may be arranged on the first color filter 126a, and the 1-2 light-blocking pattern LBa2 may be disposed on the 1-1 light-blocking pattern LBa1.

In an embodiment, the second light-blocking pattern LBb may include a 2-1 light-blocking pattern LBb1 including the same material as the first color filter 126a and a 2-2 light-blocking pattern LBb2 including the same material as the third color filter 126c. The 2-1 light-blocking pattern LBb1 may be disposed directly on an upper surface of the second touch insulating layer 124. The 2-2 light-blocking pattern LBb2 may be disposed directly on an upper surface of the second color filter 126b. According to an embodiment, the 2-1 light-blocking pattern LBb1 may be formed simultaneously with the first color filter 126a. According to an embodiment, the 2-2 light-blocking pattern LBb2 may be formed simultaneously with the third color filter 126c. According to the present embodiment, since the color filters may be formed in the order of the first color filter 126a, the second color filter 126b, and the third color filter 126c, the 2-1 light-blocking pattern LBb1 may be arranged below the second color filter 126b, and the 2-2 light-blocking pattern LBb2 may be disposed over the second color filter 126b. The 2-1 light-blocking pattern LBb1 and the 2-2 light-blocking pattern LBb2 may overlap each other (e.g., in the z direction).

The third light-blocking pattern LBc may include a 3-1 light-blocking pattern LBc1 including the same material as the first color filter 126a and a 3-2 light-blocking pattern LBc2 including the same material as the second color filter 126b. The 3-1 light-blocking pattern LBc1 may be disposed directly on an upper surface of the second touch insulating layer 124. The 3-2 light-blocking pattern LBc2 may be disposed directly on an upper surface of the 3-1 light-blocking pattern LBc1. According to an embodiment, the 3-1 light-blocking pattern LBc1 may be formed simultaneously with the first color filter 126a. According to an embodiment, the 3-2 light-blocking pattern LBc2 may be formed simultaneously with the second color filter 126b. According to the present embodiment, since the color filters may be formed in the order of the first color filter 126a, the second color filter 126b, and the third color filter 126c, the 3-1 light-blocking pattern LBc1 and the 3-2 light-blocking pattern LBc2 may be arranged below the third color filter 126c, and the 3-2 light-blocking pattern LBc2 may be disposed on (e.g., disposed directly thereon) the 3-1 light-blocking pattern LBc1.

A method, performed by the first, second, and third light-blocking patterns LBa, LBb, and LBc, of blocking external light is the same as that described above with reference to FIGS. 10 and 11. The stacking order of the color filters is not necessarily limited to that shown in FIG. 12, and the color filters may be stacked in a different order. Accordingly, an upper-lower relationship between each light-blocking pattern and a color filter corresponding thereto may also be variously modified.

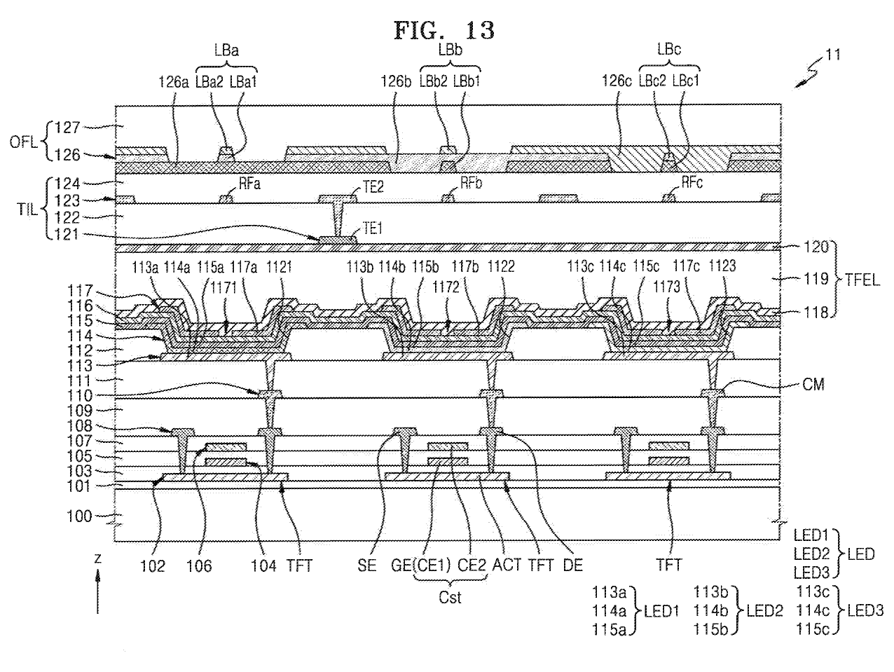

FIG. 13 is a cross-sectional view of the display panel 11 according to an embodiment. FIG. 13 may be a cross-sectional view of the display area DA of the display panel 11.

Referring to FIG. 13, the light-blocking layer 125 (see FIG. 10) may be omitted in the optical functional layer OFL.

The color filters of the color filter layer 126 may overlap each other in areas overlapping with the pixel defining layer 112. For example, in an embodiment the first color filter 126a, the second color filter 126b, and the third color filter 126c may overlap each other (e.g., in the z direction) in areas overlapping with the pixel defining layer 112. FIG. 13 illustrates an embodiment in which the second color filter 126b is disposed on (e.g., disposed directly thereon) the first color filter 126a and the third color filter 126c is disposed on (e.g., disposed directly thereon) the second color filter 126b.

The stacking order of the color filters is not necessarily limited to that shown in FIG. 13, and the color filters may be stacked in a different order. Accordingly, an upper-lower relationship between each light-blocking pattern and a color filter corresponding thereto may also be variously modified.

As described above, the first color filter 126a, the second color filter 126b, and the third color filter 126c may transmit light beams of different colors (e.g., wavelength bands), respectively. Accordingly, the areas overlapping with the pixel defining layer 112, namely, areas where the first color filter 126a, the second color filter 126b, and the third color filter 126c overlap each other, may not transmit light. For example, the areas where the first color filter 126a, the second color filter 126b, and the third color filter 126c overlap each other may also perform a function of the light-blocking layer 125 (see FIG. 10).

FIG. 13 illustrates an embodiment in which all of the first color filter 126a, the second color filter 126b, and the third color filter 126c overlap each other in the areas overlapping with the pixel defining layer 112 (e.g., in the z direction), but the present disclosure is not necessarily limited thereto. Since a light-blocking effect may be still obtained by overlapping only two color filters selected from the first color filter 126a, the second color filter 126b, and the third color filter 126c, the two color filters may also overlap each other in an area overlapping the pixel defining layer 112 to perform the role of the light-blocking layer 125 (see FIG. 10). According to an embodiment, the first color filter 126a and the second color filter 126b may overlap each other in an area between the first light-emitting diode LED1 and the second light-emitting diode LED2, and the third color filter 126c may not be arranged thereon. According to an embodiment, the second color filter 126b and the third color filter 126c may overlap each other in an area between the second light-emitting diode LED2 and the third light-emitting diode LED3, and the first color filter 126a may not be arranged thereon. According to an embodiment, the third color filter 126c and the first color filter 126a may overlap each other in an area between the third light-emitting diode LED3 and the first light-emitting diode LED1, and the second color filter 126b may not be arranged thereon.

In an embodiment, a corresponding opening may be included in the color filter layer 126 to allow light emitted by a light-emitting diode LED to pass through the color filter layer 126. According to an embodiment, openings may be included in the second color filter 126b and the third color filter 126c in areas overlapping the first light-emitting diode LED1. According to an embodiment, openings may be included in the first color filter 126a and the third color filter 126c in areas overlapping the second light-emitting diode LED2 (e.g., in the z direction). According to an embodiment, openings may be included in the first color filter 126a and the second color filter 126b in areas overlapping the third light-emitting diode LED3 (e.g., in the z direction).

According to an embodiment, the first color filter 126a, the 2-1 light-blocking pattern LBb1, and the 3-1 light-blocking pattern LBc1 may be formed simultaneously with each other. In an embodiment, the first color filter 126a may be patterned to include an opening overlapping the second light-emitting diode LED2 (e.g., in the z direction) and a 2-1 light-blocking pattern LBb1 disposed within the opening and overlapping the second opening 1172 of the second absorption pattern 117b. The first color filter 126a may also be patterned to include an opening overlapping the third light-emitting diode LED3 (e.g., in the z direction) and a 3-1 light-blocking pattern LBc1 disposed within the opening and overlapping the third opening 1173 of the third absorption pattern 117c (e.g., in the z direction).

According to an embodiment, the second color filter 126b, the 1-1 light-blocking pattern LBa1, and the 3-2 light-blocking pattern LBc2 may be formed simultaneously with each other. The second color filter 126b may be patterned to include an opening overlapping the first light-emitting diode LED1 (e.g., in the z direction) and a 1-1 light-blocking pattern LBa1 disposed within the opening and overlapping the first opening 1171 of the first absorption pattern 117a. The second color filter 126b may also be patterned to include an opening overlapping the third light-emitting diode LED3 (e.g., in the z direction) and a 3-2 light-blocking pattern LBc2 disposed within the opening and overlapping the third opening 1173 of the third absorption pattern 117c (e.g., in the z direction). In this embodiment, the 3-2 light-blocking pattern LBc2 may be disposed on the 3-1 light-blocking pattern LBc1.

According to an embodiment, the third color filter 126c, the 1-2 light-blocking pattern LBa2, and the 2-2 light-blocking pattern LBb2 may be formed simultaneously with each other. The third color filter 126c may be patterned to include an opening overlapping the first light-emitting diode LED1 (e.g., in the z direction) and a 1-2 light-blocking pattern LBa2 disposed within the opening and overlapping the first opening 1171 of the first absorption pattern 117a (e.g., in the z direction). In this embodiment, the 1-2 light-blocking pattern LBa2 may be disposed on the 1-1 light-blocking pattern LBa1. The third color filter 126c may also be patterned to include an opening overlapping the second light-emitting diode LED2 and a 2-2 light-blocking pattern LBb2 disposed within the opening and overlapping the second opening 1172 of the second absorption pattern 117b (e.g., in the z direction). In this embodiment, the 2-2 light-blocking pattern LBb2 may be disposed on the second color filter 126b.

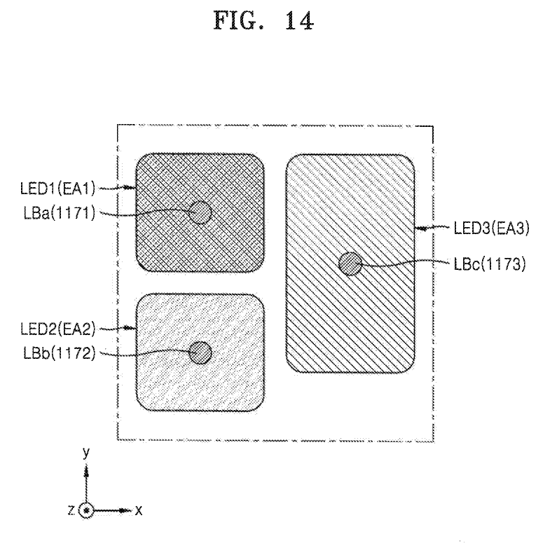

FIGS. 14 through 17 are plan views of respective portions of display panels according to several embodiments. For convenience of explanation, FIGS. 14 through 17 extract and illustrate first, second, and third light-emitting diodes LED1, LED2, and LED3.

Referring to FIGS. 14 through 17 together with FIG. 10, the first, second, and third light-emitting diodes LED1, LED2, and LED3 may have first, second, and third emission areas EA1, EA2, and EA3, respectively, and the first, second, and third emission areas EA1, EA2, and EA3 of the first, second, and third light-emitting diodes LED1, LED2, and LED3 may be defined by the first, second, and third light-emitting openings 1121, 1122, and 1123 of the pixel defining layer 112.

According to an embodiment, the first emission area EA1 of the first light-emitting diode LED1 may be defined by the first light-emitting opening 1121 of the pixel defining layer 112. According to an embodiment, the second emission area EA2 of the second light-emitting diode LED2 may be defined by the second light-emitting opening 1122 of the pixel defining layer 112. According to an embodiment, the third emission area EA3 of the third light-emitting diode LED3 may be defined by the third light-emitting opening 1123 of the pixel defining layer 112.

According to an embodiment, the first, second, and third emission areas EA1, EA2, and EA3 of the first, second, and third light-emitting diodes LED1, LED2, and LED3, or the first, second, and third light-emitting openings 1121, 1122, and 1123 of the pixel defining layer 112 may each have a rectangular shape with rounded corners, as illustrated in FIG. 14 (e.g., in a plan view).

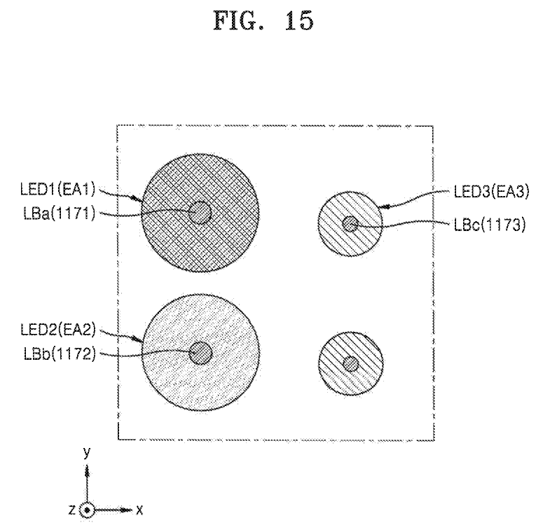

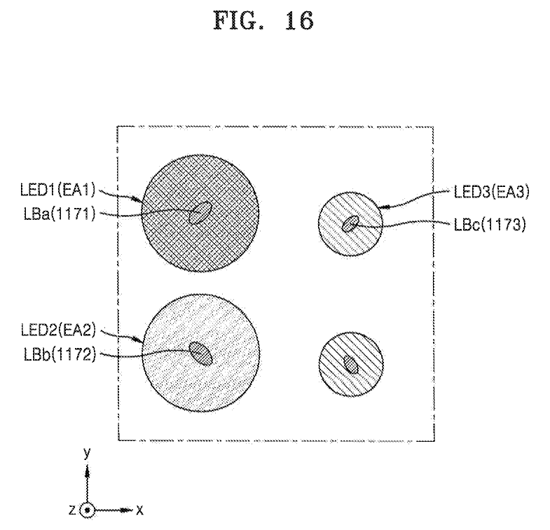

According to an embodiment, the first, second, and third emission areas EA1, EA2, and EA3 of the first, second, and third light-emitting diodes LED1, LED2, and LED3, or the first, second, and third light-emitting openings 1121, 1122, and 1123 of the pixel defining layer 112 may each have a circular shape, as illustrated in FIGS. 15 and 16 (e.g., in a plan view).

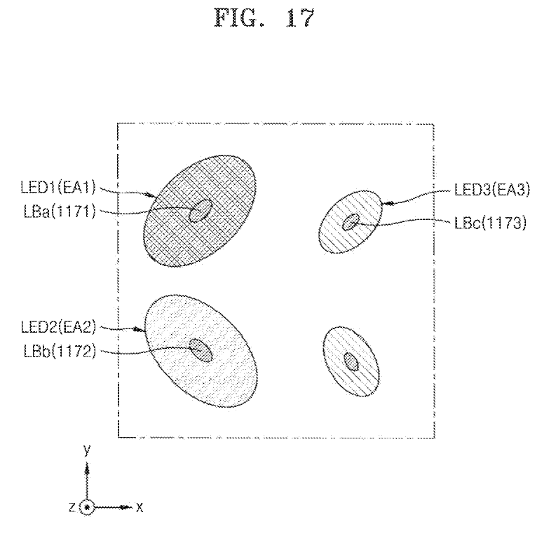

According to an embodiment, the first, second, and third emission areas EA1, EA2, and EA3 of the first, second, and third light-emitting diodes LED1, LED2, and LED3, or the first, second, and third light-emitting openings 1121, 1122, and 1123 of the pixel defining layer 112 may each have an oval shape, as illustrated in FIG. 17 (e.g., in a plan view).

An absorption pattern, a reflection pattern, and a light-blocking pattern corresponding to the light-emitting diode LED may be provided. 'In a top view' used herein may refer to, for example, when viewed in a z direction.

According to an embodiment, the first light-emitting diode LED1 may include the first absorption pattern 117a, the first reflection pattern RFa, and the first light-blocking pattern LBa. The first absorption pattern 117a may include the first opening 1171 overlapping the first reflection pattern RFa and the first light-blocking pattern LBa. In a top view, the first reflection pattern RFa, the first light-blocking pattern LBa, and the first opening 1171 may completely overlap each other.

According to an embodiment, the second light-emitting diode LED2 may include the second absorption pattern 117b, the second reflection pattern RFb, and the second light-blocking pattern LBb. The second absorption pattern 117b may include the second opening 1172 overlapping the second reflection pattern RFb and the second light-blocking pattern LBb. In a top view, the second reflection pattern RFb, the second light-blocking pattern LBb, and the second opening 1172 may completely overlap each other.

According to an embodiment, the third light-emitting diode LED3 may include the third absorption pattern 117c, the third reflection pattern RFc, and the third light-blocking pattern LBc. The third absorption pattern 117c may include the third opening 1173 overlapping the third reflection pattern RFc and the third light-blocking pattern LBc. In a top view, the third reflection pattern RFc, the third light-blocking pattern LBc, and the third opening 1173 may completely overlap each other.

According to an embodiment, as illustrated in FIGS. 14 and 16, the first, second, and third openings 1171, 1172, and 1173 or the first, second, and third light-blocking patterns LBa, LBb, and LBc may have different shapes (e.g., in a plan view) from the first, second, and third emission areas EA1, EA2, and EA3 of the first, second, and third light-emitting diodes LED1, LED2, and LED3 or the first, second, and third light-emitting openings 1121, 1122, and 1123 of the pixel defining layer 112.

For example, in the embodiment illustrated in FIG. 14, the first, second, and third openings 1171, 1172, and 1173 or the first, second, and third light-blocking patterns LBa, LBb, and LBc may each have a circular shape (e.g., in a plan view), and the first, second, and third emission areas EA1, EA2, and EA3 or the first, second, and third light-emitting openings 1121, 1122, and 1123 may each have a rectangular shape with rounded corners (e.g., in a plan view). As another example, in the embodiment illustrated in FIG. 16, the first, second, and third openings 1171, 1172, and 1173 or the first, second, and third light-blocking patterns LBa, LBb, and LBc may each have an oval shape (e.g., in a plan view), and the first, second, and third emission areas EA1, EA2, and EA3 or the first, second, and third light-emitting openings 1121, 1122, and 1123 may each have a circular shape (e.g., in a plan view).

According to an embodiment, as illustrated in FIGS. 15 and 17, the first, second, and third openings 1171, 1172, and 1173 or the first, second, and third light-blocking patterns LBa, LBb, and LBc may have the same shapes as and different dimensions (e.g., area in a plan view) from the first, second, and third emission areas EA1, EA2, and EA3 of the first, second, and third light-emitting diodes LED1, LED2, and LED3 or the first, second, and third light-emitting openings 1121, 1122, and 1123 of the pixel defining layer 112.

For example, in the embodiment illustrated in FIG. 15, the first, second, and third openings 1171, 1172, and 1173 or the first, second, and third light-blocking patterns LBa, LBb, and LBc may each have a circular shape (e.g., in a plan view), and the first, second, and third emission areas EA1, EA2, and EA3 or the first, second, and third light-emitting openings 1121, 1122, and 1123 may each have a larger circular shape (e.g., in a plan view). As another example, in the embodiment illustrated in FIG. 17, the first, second, and third openings 1171, 1172, and 1173 or the first, second, and third light-blocking patterns LBa, LBb, and LBc may each have an oval shape (e.g., in a plan view), and the first, second, and third emission areas EA1, EA2, and EA3 or the first, second, and third light-emitting openings 1121, 1122, and 1123 may each have a larger oval shape (e.g., in a plan view).

According to an embodiment, in a top view (e.g., in a plan view), an area of the first opening 1171 (or an area of the first reflection pattern RFa or an area of the first light-blocking pattern LBa) may be in a range of about 5% to about 15% of an area of the first emission area EA1 (or an area of the first light-emitting opening 1121).

According to an embodiment, in a top view (e.g., in a plan view), an area of the second opening 1172 (or an area of the second reflection pattern RFb or an area of the second light-blocking pattern LBb) may be in a range of about 5% to about 15% of an area of the second emission area EA2 (or an area of the second light-emitting opening 1122).

According to an embodiment, in a top view (e.g., in a plan view), an area of the third opening 1173 (or an area of the third reflection pattern RFc or an area of the third light-blocking pattern LBc) may be in a range of about 5% to about 15% of an area of the third emission area EA3 (or an area of the third light-emitting opening 1123).

According to an embodiment as described above, a display panel having a structure capable of transmitting light emitted by a light-emitting diode to a user by recycling the light through reflection while reducing external light reflectance, and an electronic device including the display panel are provided. Accordingly, the display panel and the electronic device may have increased display qualities.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display panel comprising:
a substrate;
a first light-emitting diode disposed on the substrate, the first light-emitting diode including a first pixel electrode, an intermediate layer, and an opposite electrode;
a first absorption pattern disposed on the first light-emitting diode, the first absorption pattern overlapping the first pixel electrode in a plan view and including an opening overlapping a portion of the first pixel electrode in the plan view;
a first reflection pattern disposed on the first absorption pattern and overlapping the opening of the first absorption pattern in the plan view; and
a first light-blocking pattern disposed on the first reflection pattern and overlapping the opening of the first absorption pattern in the plan view.

2. The display panel of claim 1, further comprising:
a touch input layer including a first touch electrode disposed on the first absorption pattern and a second touch electrode disposed on the first touch electrode,
wherein the first reflection pattern is disposed on a same layer as one of the first touch electrode and the second touch electrode.

3. The display panel of claim 2, wherein the first reflection pattern is disposed on the same layer as the first touch electrode.

4. The display panel of claim 1, wherein:
the first absorption pattern includes a plurality of openings; and
the display panel includes a plurality of first reflection patterns overlapping the plurality of openings, respectively, and a plurality of first light-blocking patterns overlapping the plurality of openings, respectively.

5. The display panel of claim 1, wherein the first light-blocking pattern includes a material that transmits light of a different color from light emitted by the first light-emitting diode.

6. The display panel of claim 1, further comprising:
a reflection control layer disposed on the first light-blocking pattern,
wherein the reflection control layer absorbs light of a different wavelength band from light emitted by the first light-emitting diode.

7. The display panel of claim 1, further comprising:
a second light-emitting diode disposed on the substrate, the second light-emitting diode is spaced apart from the first light-emitting diode;
a first color filter disposed on the first light-emitting diode, the first color filter transmitting light having a same color as light emitted by the first light-emitting diode; and
a second color filter disposed on the second light-emitting diode, the second color filter transmitting light having a same color as light emitted by the second light-emitting diode.

8. The display panel of claim 7, wherein the first color filter covers the first light-blocking pattern.

9. The display panel of claim 7, further comprising a light-blocking layer disposed on the first reflection pattern, the light-blocking layer including a first hole overlapping the first light-emitting diode.

10. The display panel of claim 9, wherein the first light-blocking pattern is disposed on a same layer as the light-blocking layer.

11. The display panel of claim 7, wherein the first light-blocking pattern includes a same material as a material included in the second color filter.

12. The display panel of claim 11, wherein the first light-blocking pattern is disposed on the first color filter.

13. The display panel of claim 7, further comprising:
a second light-blocking pattern disposed on the second light-emitting diode,
wherein the second light-blocking pattern includes a same material as a material included in the first color filter.

14. The display panel of claim 7, wherein the first color filter and the second color filter overlap each other in an area between the first light-emitting diode and the second light-emitting diode.

15. The display panel of claim 1, further comprising a pixel defining layer disposed on the first pixel electrode, the pixel defining layer including a light-emitting opening that defines an emission area of the first light-emitting diode.

16. The display panel of claim 15, wherein, in the plan view, an area of the opening of the first absorption pattern is in a range of about 5% to about 15% of an area of the light-emitting opening of the pixel defining layer.

17. The display panel of claim 15, wherein, in the plan view, a shape of the opening of the first absorption pattern and a shape of the light-emitting opening of the pixel defining layer are different from each other.

18. An electronic device including a display panel, the display panel comprising:
a substrate;
a first light-emitting diode disposed on the substrate, the first light-emitting diode including a first pixel electrode, an intermediate layer, and an opposite electrode;
a first absorption pattern disposed on the first light-emitting diode, the first absorption pattern overlapping the first pixel electrode in a plan view and including an opening overlapping a portion of the first pixel electrode in the plan view;
a first reflection pattern disposed on the first absorption pattern and overlapping the opening of the first absorption pattern in the plan view; and
a first light-blocking pattern disposed on the first reflection pattern and overlapping the opening of the first absorption pattern in the plan view.

19. The electronic device of claim 18, further comprising:
a touch input layer including a first touch electrode disposed on the first absorption pattern and a second touch electrode disposed on the first touch electrode,
wherein the first reflection pattern is disposed on a same layer as one of the first touch electrode and the second touch electrode.

20. The electronic device of claim 18, further comprising:
a reflection control layer disposed on the first light-blocking pattern,
wherein the reflection control layer absorbs light of a different wavelength band from light emitted by the first light-emitting diode.
